(19) United States
(12) Patent Application Publication
(10) Pub. No.: US 2018/0306851 A1
(43) Pub. Date: Oct. 25, 2018

(54) PRODUCT STRATIFICATION DEVICE, PRODUCT STRATIFICATION METHOD, AND COMPUTER PROGRAM

(71) Applicant: Murata Manufacturing Co., Ltd., Nagaokakyo-shi (JP)

(72) Inventors: Teruhisa Tsuru, Nagaokakyo-shi (JP); Yuki Matsuno, Nagaokakyo-shi (JP)

(21) Appl. No.: 16/021,467

(22) Filed: Jun. 28, 2018

Related U.S. Application Data
(63) Continuation of application No. PCT/JP2016/085864, filed on Dec. 2, 2016.

(30) Foreign Application Priority Data
Jan. 8, 2016 (JP) 2016-002608

(51) Int. Cl. G01R 31/01; G06Q 50/04

(52) U.S. Cl. CPC G01R 31/016; G06Q 50/04

(57) ABSTRACT

A product stratification device calculates a standard deviation for characteristic value variation of products. The device stratifies products into a plurality of ranks based on measured characteristic values. The device then calculates an average of the characteristic values and a deemed standard deviation that corresponds to a standard deviation for variation in the characteristic values. The characteristic values for each product belonging to one or more of the plurality of ranks are then re-measured, and the products are re-stratified into the plurality of ranks based on the re-measured characteristic values. An estimation number of products belonging to each rank is estimated based on the probability distribution for the average and the deemed standard deviation for the products. Based on the estimation number, measured value variation of the products is calculated for each item and can be used for determining whether the products are defective or non-defective.

### CROSS REFERENCE TO RELATED APPLICATIONS

The present application is a continuation of PCT/JP2016/085864 filed Dec. 2, 2016, which claims priority to Japanese Patent Application No. 2016-002608, filed Jan. 8, 2016, the entire contents of each of which are incorporated herein by reference.

### TECHNICAL FIELD

The present disclosure relates to a product stratification device, a product stratification method, and a computer program for stratifying products.

### BACKGROUND ART

Before shipment of products, characteristic values indicating predetermined characteristics of the products are measured, and the products are stratified into non-defectives and defectives depending on whether each of the products satisfies a predetermined standard. Such product stratification is performed by comparing the characteristic values of the products measured by a product stratification device with an inspection standard stricter than a product standard (i.e., a characteristic value required for the products). A case where variation in the characteristic values measured of the products only includes variation in the characteristic values of the products themselves allows the product stratification device to correctly stratify the products into non-defectives and defectives even with the inspection standard is defined to be identical to the product standard.

However, the variation in the characteristic values measured of the products includes not only the variation in the characteristic values of the products themselves, but also variation in measured values of a measuring system. Thus, the products determined to be non-defectives in the stratification performed by the product stratification device may include a defective product, or the products determined to be defectives may include a non-defective product. Herein, a probability that a defective product is incorrectly determined to be a non-defective is called a “consumer's risk”, and a probability that a non-defective is incorrectly determined to be a defective is called a “producer's risk”.

Non Patent Documents 1 and 2 (identified below) disclose methods of calculating the consumer's risk and the producer's risk. In particular, Non Patent Document 1 discloses a method of calculating, by the Monte Carlo method, the consumer's risk and the producer's risk to a product stratification device. Moreover, Non Patent Document 2 discloses a method of calculating, by a double integral equation, the consumer's risk and the producer's risk assuming that the variation in the characteristic values and the variation in the measured values are normally distributed.

When the consumer's risk and the producer's risk are calculated by one of the methods disclosed in Non Patent Documents 1 and 2, the variation in the characteristic values of the products themselves, the variation in the measured values of the measuring system, and the like cannot be calculated. Thus, Patent Document 1 discloses a product discriminating device configured to change the variables of the probability distribution for the deemed standard deviation such that the number of the products that belong to at least one of the plurality of ranks as a result of a single re-discrimination is approximately equal to the estimation number of the products that belong to the rank and then calculate the variables thus changed as the standard deviation for the variation in the characteristic values of the products and the standard deviation for the variation in the measured values.
Patent Document 1: Japanese Patent No. 5287985.
Non Patent Document 1: M. Dobbert, “Understanding Measurement Risk”, NCSL International Workshop and Symposium, August 2007.
Non Patent Document 2: David Deaver, “Managing Calibration Confidence in the Real World”, NCSL International Workshop and Symposium, 1995.

The product discriminating device disclosed in Patent Document 1 is configured to calculate the variation in the measured values in stratification for a single item. Specifically, as long as stratification is performed for a single item, the standard deviation GRR for the variation in the measured values in which the number of the characteristic values acquired for each of the plurality of ranks in the first stratification is equal to the number resulting from re-stratification on the products that belong to any rank in the first stratification and the number calculated from the ratio between the consumer's risk and the producer's risk can be calculated.

However, when the standard deviations for the variation in the measured values and the variation in the characteristic values are calculated through stratification for multiple items, the stratification needs to be performed twice for each of the items, increasing the measurement workload, which in turn increases the production time and the production cost.

### SUMMARY OF THE INVENTION

In view of the foregoing circumstances, it is an object of the present disclosure to provide a product stratification device, a product stratification method, and a computer program capable of calculating a standard deviation for characteristic value variation of products and a standard deviation for measured value variation in a short period of time without the need of multiple times of stratification for each item.

To achieve the above-described object, a product stratification device according to an exemplary embodiment of the present disclosure includes a measuring part configured to measure characteristic values for a plurality of items indicating predetermined characteristics of products; a stratifying module configured to stratify the products into a predetermined plurality of ranks based on pluralities of the characteristic values measured; a deemed standard deviation calculating module configured to calculate, for each of the plurality of items, an average of the characteristic values measured and a deemed standard deviation corresponding to a standard deviation for variation in the characteristic values; a re-stratifying module configured to re-measure, for each of the plurality of items, the characteristic values of the products that belong to at least one of the predetermined plurality of ranks as a result of stratification and re-stratify, for each of the plurality of items, the products into the predetermined plurality of ranks based on the characteristic values re-measured; a rank-by-rank estimation number calculating module configured to estimate, for each of the plurality of items, an estimation number of the products that belong to each of the predetermined plurality of ranks in a case where at least one time of re-stratification is performed, based on a probability distribution for the average and the deemed standard deviation for the products calculated for each of the plurality of items; and a variation calculating module configured to calculate, for each of the plurality of items, measured value variation of the products based on the estimation number.

According to the exemplary embodiment, the characteristic values of the products that belong to at least one of the predetermined plurality of ranks as a result of stratification are re-measured for each of the plurality of items, and the products are re-stratified, for each of the plurality of items, into the predetermined plurality of ranks based on the characteristic values re-measured, thus eliminating the need for re-measuring the characteristic values of all the products and the need for performing repeated measurements, such as the measurement system analysis (MSA) method, involving tasks such as detachment of the measurement jig. Furthermore, the estimation number of the products that belong to each of the predetermined plurality of ranks in a case where at least one time of re-stratification is performed is estimated for each of the plurality of items based on the probability distribution for the average and the deemed standard deviation for the products calculated for each of the plurality of items, and the measured value variation of the products is calculated for each of the plurality of items based on the estimation number, thus allowing the measured value variation σ_{GRR} to be calculated from the probability distribution for the products determined in the first stratification. Therefore, the overall measurement workload can be reduced, and a reduction in the production time and a decrease in the production cost can be achieved.

Furthermore, it is preferred that, in the exemplary product stratification device, the predetermined plurality of ranks are provided based on a predetermined inspection standard that defines an upper limit and a lower limit of the characteristic values used for determining whether each of the products is a non-defective. Moreover, the re-stratifying module is configured to re-stratify, for each of the plurality of items, the products that belong to one of the predetermined plurality of ranks that has a range of the characteristic values from the lower limit to the upper limit, both inclusive, defined by the predetermined inspection standard; and the variation calculating module is configured to calculate a consumer's risk and a producer's risk from the estimation number, for each of the plurality of items, of the products that belong to each of the predetermined plurality of ranks and calculate the measured value variation in which a value obtained by multiplication of a sum of the consumer's risk and the producer's risk calculated by a total number of the products is equal to an actual number of the products determined to be defectives.

According to exemplary embodiment of the present disclosure, the consumer's risk and the producer's risk are calculated from the estimation number, for each of the plurality of items, of the products that belong to each of the predetermined plurality of ranks, and the measured value variation is calculated in which the value obtained by multiplication of the sum of the consumer's risk and the producer's risk calculated by the total number of the products is equal to the actual number of the products determined to be defectives, thus allowing the measured value variation σ_{GRR} to be calculated from the probability distribution for the products determined in the first stratification. Therefore, the overall measurement workload can be reduced, and a reduction in the production time and a decrease in the production cost can be achieved.

Furthermore, it is preferred that, in the exemplary product stratification device, the predetermined plurality of ranks are provided based on a predetermined inspection standard that defines an upper limit and a lower limit of the characteristic values used for determining whether each of the products is a non-defective; the re-stratifying module is configured to re-stratify, for each of the plurality of items, the products that belong to one of the predetermined plurality of ranks that has a range of the characteristic values greater than the upper limit defined by the predetermined inspection standard and the products that belong to one of the predetermined plurality of ranks that has a range of the characteristic values less than the lower limit defined by the predetermined inspection standard; and the variation calculating module is configured to calculate a consumer's risk and a producer's risk from the estimation number, for each of the plurality of items, of the products that belong to each of the predetermined plurality of ranks and calculate the measured value variation in which a value obtained by multiplication of a sum of the consumer's risk and the producer's risk calculated by a total number of the products is equal to an actual number of the products determined to be defectives.

According to exemplary embodiment of the present disclosure, the consumer's risk and the producer's risk are calculated from the estimation number, for each of the plurality of items, of the products that belong to each of the predetermined plurality of ranks, and the measured value variation is calculated in which the value obtained by multiplication of the sum of the consumer's risk and the producer's risk calculated by the total number of the products is equal to the actual number of the products determined to be defectives, thus allowing the measured value variation σ_{GRR} to be calculated from the probability distribution for the products determined in the first stratification. Therefore, the overall measurement workload can be reduced, and a reduction in the production time and a decrease in the production cost can be achieved.

Next, to achieve the above-described object, a product stratification method according to an exemplary embodiment of the present disclosure that is executable in a product stratification device configured to stratify products includes for the product stratification device, measuring characteristic values for a plurality of items indicating predetermined characteristics of products; stratifying the products into a predetermined plurality of ranks based on pluralities of the characteristic values measured; calculating, for each of the plurality of items, an average of the characteristic values measured and a deemed standard deviation corresponding to a standard deviation for variation in the characteristic values; re-measuring, for each of the plurality of items, the characteristic values of the products that belong to at least one of the predetermined plurality of ranks as a result of stratification and re-stratifying, for each of the plurality of items, the products into the predetermined plurality of ranks based on the characteristic values re-measured; estimating, for each of the plurality of items, an estimation number of the products that belong to each of the predetermined plurality of ranks in a case where at least one time of re-stratification is performed, based on a probability distribution for the average and the deemed standard deviation for the products calculated for each of the plurality of items; and calculating, for each of the plurality of items, measured value variation of the products based on the estimation number.

According to the exemplary embodiment, the characteristic values of the products that belong to at least one of the predetermined plurality of ranks as a result of stratification are re-measured for each of the plurality of items, and the products are re-stratified, for each of the plurality of items, into the predetermined plurality of ranks based on the characteristic values re-measured, thus eliminating the need for re-measuring the characteristic values of all the products and the need for performing repeated measurements, such as the measurement system analysis (MSA) method, involving tasks such as detachment of the measurement jig. Furthermore, the estimation number of the products that belong to each of the predetermined plurality of ranks in a case where at least one time of re-stratification is performed is estimated for each of the plurality of items based on the probability distribution for the average and the deemed standard deviation for the products calculated for each of the plurality of items, and the measured value variation of the products is calculated for each of the plurality of items based on the estimation number, thus allowing the measured value variation σ_{GRR} to be calculated from the probability distribution for the products determined in the first stratification. Therefore, the overall measurement workload can be reduced, and a reduction in the production time and a decrease in the production cost can be achieved.

Furthermore, it is preferred that, in the product stratification method according to the present disclosure, for the product stratification device, the predetermined plurality of ranks are provided based on a predetermined inspection standard that defines an upper limit and a lower limit of the characteristic values used for determining whether each of the products is a non-defective; the products that belong to one of the predetermined plurality of ranks that has a range of the characteristic values from the lower limit to the upper limit, both inclusive, defined by the predetermined inspection standard are re-stratified for each of the plurality of items; and a consumer's risk and a producer's risk are calculated from the estimation number, for each of the plurality of items, of the products that belong to each of the predetermined plurality of ranks and the measured value variation is calculated in which a value obtained by multiplication of a sum of the consumer's risk and the producer's risk calculated by a total number of the products is equal to an actual number of the products determined to be defectives.

According to the exemplary embodiment of the present disclosure, the consumer's risk and the producer's risk are calculated from the estimation number, for each of the plurality of items, of the products that belong to each of the predetermined plurality of ranks, and the measured value variation is calculated in which the value obtained by multiplication of the sum of the consumer's risk and the producer's risk calculated by the total number of the products is equal to the actual number of the products determined to be defectives, thus allowing the measured value variation σ_{GRR} to be calculated from the probability distribution for the products determined in the first stratification. Therefore, the overall measurement workload can be reduced, and a reduction in the production time and a decrease in the production cost can be achieved.

Furthermore, it is preferred that, in the product stratification method according to the present disclosure, for the product stratification device, the predetermined plurality of ranks are provided based on a predetermined inspection standard that defines an upper limit and a lower limit of the characteristic values used for determining whether each of the products is a non-defective. Moreover, the products that belong to one of the predetermined plurality of ranks that has a range of the characteristic values greater than the upper limit defined by the predetermined inspection standard and the products that belong to one of the predetermined plurality of ranks that has a range of the characteristic values less than the lower limit defined by the predetermined inspection standard are re-stratified for each of the plurality of items; and a consumer's risk and a producer's risk are calculated from the estimation number, for each of the plurality of items, of the products that belong to each of the predetermined plurality of ranks and the measured value variation is calculated in which a value obtained by multiplication of a sum of the consumer's risk and the producer's risk calculated by a total number of the products is equal to an actual number of the products determined to be defectives.

According to the exemplary embodiment of the present disclosure, the consumer's risk and the producer's risk are calculated from the estimation number, for each of the plurality of items, of the products that belong to each of the predetermined plurality of ranks, and the measured value variation is calculated in which the value obtained by multiplication of the sum of the consumer's risk and the producer's risk calculated by the total number of the products is equal to the actual number of the products determined to be defectives, thus allowing the measured value variation σ_{GRR} to be calculated from the probability distribution for the products determined in the first stratification. Therefore, the overall measurement workload can be reduced, and a reduction in the production time and a decrease in the production cost can be achieved.

Next, to achieve the above-described object, a computer program according to the present disclosure executable in a product stratification device configured to stratify products causes the product stratification device to measure characteristic values for a plurality of items indicating predetermined characteristics of products; stratify the products into a predetermined plurality of ranks based on pluralities of the characteristic values measured; calculate, for each of the plurality of items, an average of the characteristic values measured and a deemed standard deviation corresponding to a standard deviation for variation in the characteristic values; re-measure, for each of the plurality of items, the characteristic values of the products that belong to at least one of the predetermined plurality of ranks as a result of stratification and re-stratify, for each of the plurality of items, the products into the predetermined plurality of ranks based on the characteristic values re-measured; estimate, for each of the plurality of items, an estimation number of the products that belong to each of the predetermined plurality of ranks in a case where at least one time of re-stratification is performed, based on a probability distribution for the average and the deemed standard deviation for the products calculated for each of the plurality of items; and calculate, for each of the plurality of items, measured value variation of the products based on the estimation number.

According to the exemplary embodiment of the present disclosure, the characteristic values of the products that belong to at least one of the predetermined plurality of ranks as a result of stratification are re-measured for each of the plurality of items, and the products are re-stratified, for each of the plurality of items, into the predetermined plurality of ranks based on the characteristic values re-measured, thus eliminating the need for re-measuring the characteristic values of all the products and the need for performing repeated measurements, such as the measurement system analysis (MSA) method, involving tasks such as detachment of the measurement jig. Furthermore, the estimation number of the products that belong to each of the predetermined plurality of ranks in a case where at least one time of re-stratification is performed is estimated for each of the plurality of items based on the probability distribution for the average and the deemed standard deviation for the products calculated for each of the plurality of items, and the measured value variation of the products is calculated for each of the plurality of items based on the estimation number, thus allowing the measured value variation σ_{GRR} to be calculated from the probability distribution for the products determined in the first stratification. Therefore, the overall measurement workload can be reduced, and a reduction in the production time and a decrease in the production cost can be achieved.

Furthermore, it is preferred that, in the exemplary computer program according to the present disclosure, the predetermined plurality of ranks are provided based on a predetermined inspection standard that defines an upper limit and a lower limit of the characteristic values used for determining whether each of the products is a non-defective. Moreover, it is also preferred that the computer program further causes the product stratification device to re-stratify, for each of the plurality of items, the products that belong to one of the predetermined plurality of ranks that has a range of the characteristic values from the lower limit to the upper limit, both inclusive, defined by the predetermined inspection standard, and calculate a consumer's risk and a producer's risk from the estimation number, for each of the plurality of items, of the products that belong to each of the predetermined plurality of ranks and calculate the measured value variation in which a value obtained by multiplication of a sum of the consumer's risk and the producer's risk calculated by a total number of the products is equal to an actual number of the products determined to be defectives.

According to the exemplary embodiment of the present disclosure, the consumer's risk and the producer's risk are calculated from the estimation number, for each of the plurality of items, of the products that belong to each of the predetermined plurality of ranks, and the measured value variation is calculated in which the value obtained by multiplication of the sum of the consumer's risk and the producer's risk calculated by the total number of the products is equal to the actual number of the products determined to be defectives, thus allowing the measured value variation σ_{GRR} to be calculated from the probability distribution for the products determined in the first stratification. Therefore, the overall measurement workload can be reduced, and a reduction in the production time and a decrease in the production cost can be achieved.

Furthermore, it is preferred that, in the exemplary computer program according to the present disclosure, the predetermined plurality of ranks are provided based on a predetermined inspection standard that defines an upper limit and a lower limit of the characteristic values used for determining whether each of the products is a non-defective. Moreover, it is also preferred that the computer program further causes the product stratification device to: re-stratify, for each of the plurality of items, the products that belong to one of the predetermined plurality of ranks that has a range of the characteristic values greater than the upper limit defined by the predetermined inspection standard and the products that belong to one of the predetermined plurality of ranks that has a range of the characteristic values less than the lower limit defined by the predetermined inspection standard, and calculate a consumer's risk and a producer's risk from the estimation number, for each of the plurality of items, of the products that belong to each of the predetermined plurality of ranks and calculate the measured value variation in which a value obtained by multiplication of a sum of the consumer's risk and the producer's risk calculated by a total number of the products is equal to an actual number of the products determined to be defectives.

According to the exemplary embodiment of the present disclosure, the consumer's risk and the producer's risk are calculated from the estimation number, for each of the plurality of items, of the products that belong to each of the predetermined plurality of ranks, and the measured value variation is calculated in which the value obtained by multiplication of the sum of the consumer's risk and the producer's risk calculated by the total number of the products is equal to the actual number of the products determined to be defectives, thus allowing the measured value variation σ_{GRR} to be calculated from the probability distribution for the products determined in the first stratification. Therefore, the overall measurement workload can be reduced, and a reduction in the production time and a decrease in the production cost can be achieved.

According to the product stratification device, the product stratification method, and the computer program of the present disclosure having the above-described configuration, the estimation number of the products that belong to each of the ranks in a case where at least one time of re-stratification is performed is estimated for each of the items based on the probability distribution for the average and the deemed standard deviation for the products calculated for each of the items, and the measured value variation of the products is calculated for each of the items based on the estimation number, thus allowing the measured value variation σ_{GRR} to be calculated from the probability distribution for the products determined in the first stratification. Therefore, the overall measurement workload can be reduced, and a reduction in the production time and a decrease in the production cost can be achieved.

### BRIEF DESCRIPTION OF THE DRAWINGS

FIG. 1 is a block diagram illustrating an example configuration of a product stratification device according to a first exemplary embodiment.

FIG. 2 is a functional block diagram of the product stratification device according to the first exemplary embodiment.

FIG. 3 is a schematic graph of a probability distribution in a case where a stratifying module of the product stratification device according to the first exemplary embodiment stratifies products into a plurality of ranks.

FIGS. 4(a) and 4(b) are graphs for illustrating a method for the product stratification device according to the first exemplary embodiment to calculate an estimation number of the products belonging to each of the ranks.

FIGS. 5(a) and 5(b) are schematic graphs showing an image of re-stratification under identical standards performed by the product stratification device according to the first exemplary embodiment.

FIG. 6 is a graph for illustrating a probability distribution in stratification under the identical standards performed by the product stratification device according to the first exemplary embodiment.

FIG. 7 is a graph for illustrating a probability distribution in re-stratification performed by the product stratification device according to the first exemplary embodiment.

FIG. 8 is a flowchart showing a processing procedure in which the product stratification device according to the first exemplary embodiment calculates measured value variation.

FIG. 9 is a flowchart showing the processing procedure in which the product stratification device according to the first exemplary embodiment calculates the measured value variation.

FIGS. 10(a) and 10(b) are graphs for illustrating a method for a product stratification device according to a second exemplary embodiment to calculate an estimation number of the products belonging to each of the ranks.

FIGS. 11(a) and 11(b) are schematic graphs showing an image of re-stratification under the identical standards performed by the product stratification device according to the second exemplary embodiment.

FIG. 12 is a graph for illustrating a probability distribution in stratification under the identical standards performed by the product stratification device according to the second exemplary embodiment.

FIGS. 13(a) and 13(b) are graphs for illustrating probability distributions in re-stratification performed by the product stratification device according to the second exemplary embodiment.

FIG. 14 is a flowchart showing a processing procedure in which the product stratification device according to the second exemplary embodiment calculates measured value variation.

FIG. 15 is a flowchart showing the processing procedure in which the product stratification device according to the second exemplary embodiment calculates the measured value variation.

### DETAILED DESCRIPTION OF EXEMPLARY EMBODIMENTS

A detailed description of a product stratification device according to exemplary embodiments will be given below with reference to the drawings. The product stratification device is configured to calculate characteristic value variation of products themselves and measured value variation of a measuring system. It is noted that the following exemplary embodiments are not intended to limit the invention recited in the claims, nor are all combinations of the characteristic matters described in the exemplary embodiments essential for solving the problems of convention systems and methods.

In the following exemplary embodiments, a description will be given of a product stratification device that is a computer system in which a computer program is installed, but it is apparent to a person skilled in the art that the present invention can be partially implemented in the form of a computer-executable computer program. Therefore, the exemplary embodiments may include one of an embodiment in the form of hardware, an embodiment in the form of software, and an embodiment in the form of a combination of software and hardware, as the product stratification device. Such a computer program can be recorded on any computer-readable recording medium such as a hard disk, a digital versatile disc (DVD), a compact disc (CD), an optical storage device, or a magnetic storage device.

### First Embodiment

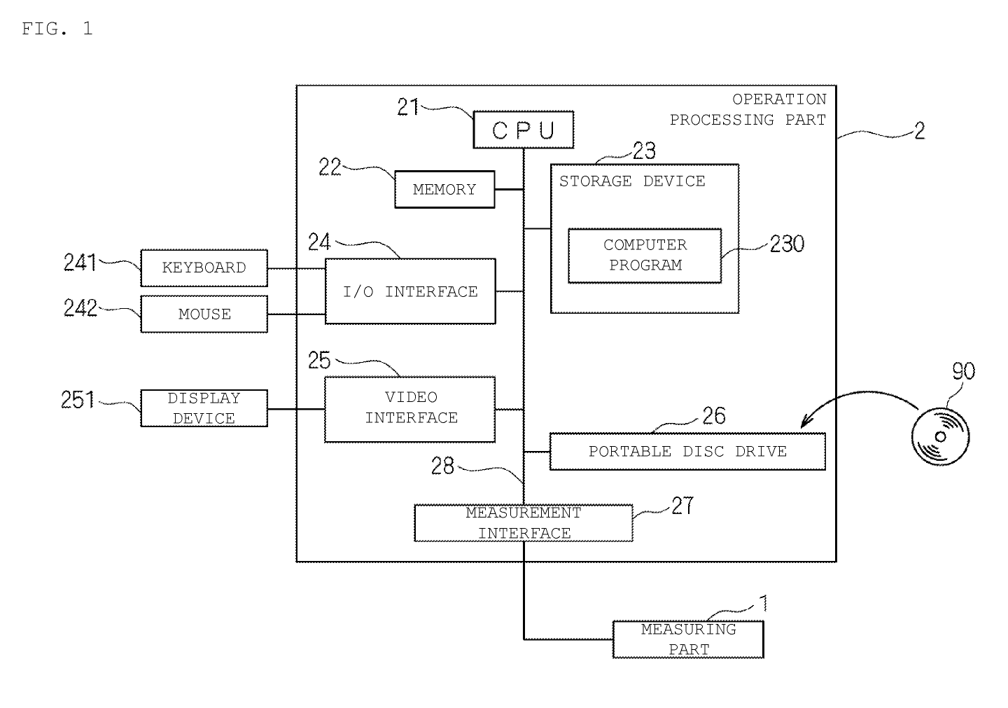

FIG. 1 is a block diagram illustrating an example configuration of a product stratification device according to a first exemplary embodiment. The product stratification device according to the first embodiment includes a measuring part or component 1 configured to measure a characteristic value indicating a predetermined characteristic of a product, and an operation processing part 2 configured to perform an operation on the characteristic value measured.

The measuring part 1 is configured to measure characteristic values for a plurality of items indicating predetermined characteristics of the product. For example, in a case where the product is a ceramic capacitor, the measuring part 1 can be an electronic device configured to measure capacitance, which is the characteristic value of the product. The hardware configuration of the measuring part 1 capable of measuring capacitance includes an LCR meter.

The operation processing part 2 includes at least a central processing unit (CPU) 21, a memory 22, a storage device 23, an input/output (I/O) interface 24, a video interface 25, a portable disc drive 26, a measurement interface 27, and an internal bus 28. The internal bus 28 connects the above-described hardware components to each other.

The CPU 21 is connected, through the internal bus 28, to each of the above-described hardware components included in the operation processing part 2. The CPU 21 is configured to control the operation of each of the above-described hardware components and execute various software functions in accordance with a computer program 230 stored in the storage device 23. The memory 22 is a volatile memory such as a static random access memory (SRAM) or a synchronous dynamic random access memory (SDRAM), where a load module is loaded at the start of the execution of the computer program 230 and temporary data and the like generated during the execution of the computer program 230 are stored.

The storage device 23 is, for example, a built-in fixed storage device (hard disk) or a read only memory (ROM). The computer program 230 to be stored in the storage device 23 is downloaded, by the portable disc drive 26, from a portable recording medium 90 such as a DVD or a CD-ROM where information such as a program and data is recorded. The computer program 230 is loaded, at the start of the execution, from the storage device 23 to the memory 22 and then executed. It is noted that the computer program 230 may be a computer program downloaded from an external computer connected to a network.

The measurement interface 27 is connected to the internal bus 28 and to the measuring part 1, thus allowing the measuring part 1 and the operation processing part 2 to transmit and receive characteristic values measured, control signals, and the like to and from each other.

The I/O interface 24 is connected to a data input medium such as a keyboard 241 or a mouse 242 and configured to receive the input of data. The video interface 25 is connected to a display device 251 such as a cathode ray tube (CRT) monitor or a liquid crystal display (LCD) and configured to display predetermined images.

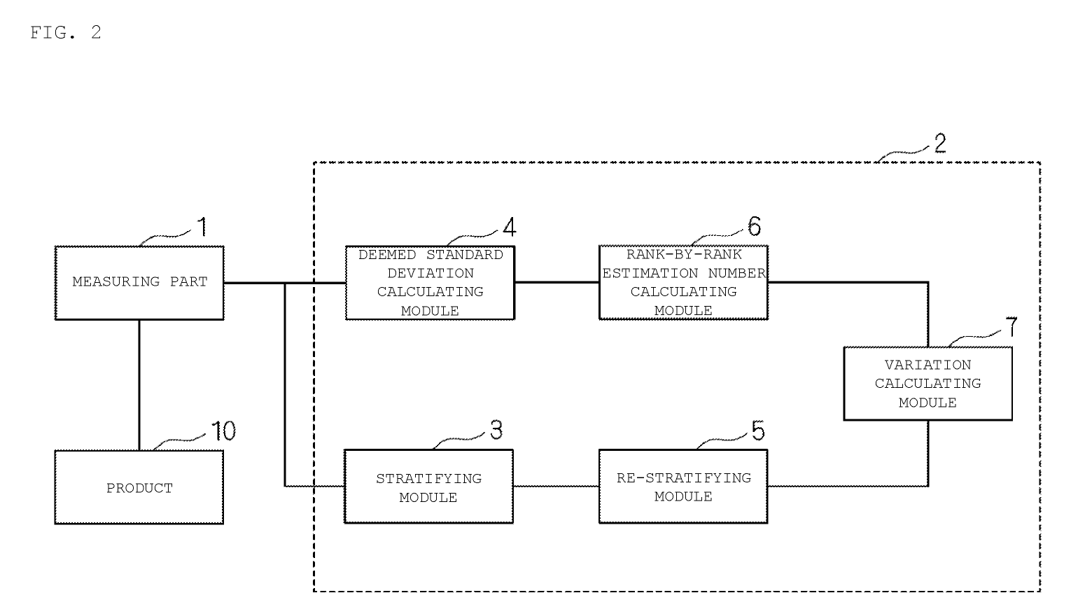

The operation of the product stratification device having the above-described configuration will be described below. FIG. 2 is a functional block diagram of the product stratification device according to the first exemplary embodiment. The measuring part 1 is configured to measure a characteristic value indicating a predetermined characteristic of a product 10.

A stratifying module 3 is configured to stratify the products 10 into a predetermined plurality of ranks based on a plurality of the characteristic values measured by the measuring part 1. The ranks into which the products 10 are stratified are provided based on, for example, a predetermined inspection standard defining an upper limit and a lower limit of the characteristic values used for determining whether each of the products 10 is a non-defective. It is noted that, in the first embodiment, an example where the inspection standard is defined to be identical to a product standard will be described. FIG. 3 is a schematic graph of a probability distribution in a case where the stratifying module 3 of the product stratification device according to the first exemplary embodiment stratifies the products 10 into the plurality of ranks. FIG. 3 shows the probability distribution of the characteristic values measured of the products 10, with the horizontal axis indicating the characteristic values of the products 10 and the vertical axis indicating the number of the products 10. The probability distribution of the characteristic values measured of the products 10 is a normal distribution.

Furthermore, in FIG. 3, the upper limit and the lower limit of the characteristic values defined by the predetermined inspection standard are shown. The stratifying module 3 is configured to stratify the products 10 into a rank A, a rank B, and a rank C. The rank A is a range of the characteristic values less than the lower limit, the rank B is a range of the characteristic values from the lower limit to the upper limit, both inclusive, and the rank C is a range of the characteristic values greater than the upper limit. It is noted that the products 10 belonging to the rank B are determined to be non-defectives products based on the inspection standard, and the products 10 belonging to the rank A and the rank C are determined to be defectives products based on the inspection standard.

Returning to FIG. 2, a deemed standard deviation calculating module 4 (i.e., a deemed standard deviation calculator) is configured to calculate, for each of the items, an average of the characteristic values measured and a deemed standard deviation corresponding to a standard deviation for variation in the characteristic values. It is noted that the deemed standard deviation calculating module 4 is capable of calculating not only the deemed standard deviation, but also the average of the characteristic values measured of the products 10.

A re-stratifying module 5 is configured to re-measure, for each of the items, the characteristic values of the products 10 that belong to at least one of the predetermined plurality of ranks as a result of stratification performed by the stratifying module 3 and re-stratify, for each of the items, the products 10 into the predetermined plurality of ranks based on the characteristic values re-measured. The fact that some of the products 10 belong to the rank A or C as a result of re-stratification performed by the re-stratifying module 5 indicates, as described above, the existence of not only variation in the characteristic values of the products themselves (characteristic value variation), but also measured value variation. A deemed standard deviation TV corresponding to the standard deviation for the variation in the characteristic values measured by the measuring part 1 can be expressed by (Equation 1), where a standard deviation PV represents the characteristic value variation and a standard deviation GRR represents the measured value variation.

[Math. 1]

TV²=PV²+GRR² (Equation 1)

Therefore, characteristic value variation σ_{PV} of the products 10 can be determined from total variation σ_{TV} and measured value variation σ_{GRR} based on (Equation 2).

[Math. 2]

σ_{PV}=\sqrt{σ_{TC}²−σ_{GRR}²} (Equation 2)

A rank-by-rank estimation number calculating module 6 (i.e., an estimation number calculator) is configured to estimate, for each of the items, an estimation number of the products 10 that belong to each of the ranks in a case where at least one time of re-stratification is performed, based on the probability distribution for the average and the deemed standard deviation for the products 10 calculated for each of the items.

In the first embodiment, re-stratification is performed on the products 10 belonging to the rank B, and the measured value variation σ_{GRR} is calculated for each of the items. Specifically, in a case where the proportion of non-defectives is relatively high, re-stratification on the non-defectives for calculating the measured value variation σ_{GRR} requires a large amount of operation time. Thus, re-stratification is performed on the products 10 belonging to the rank B assuming that a probability distribution is identical to the probability distribution for each of the items resulting from the first stratification, that is, an average and a standard deviation are respectively identical to the average and the deemed standard deviation of the characteristic values measured, thus significantly reducing the operation processing load.

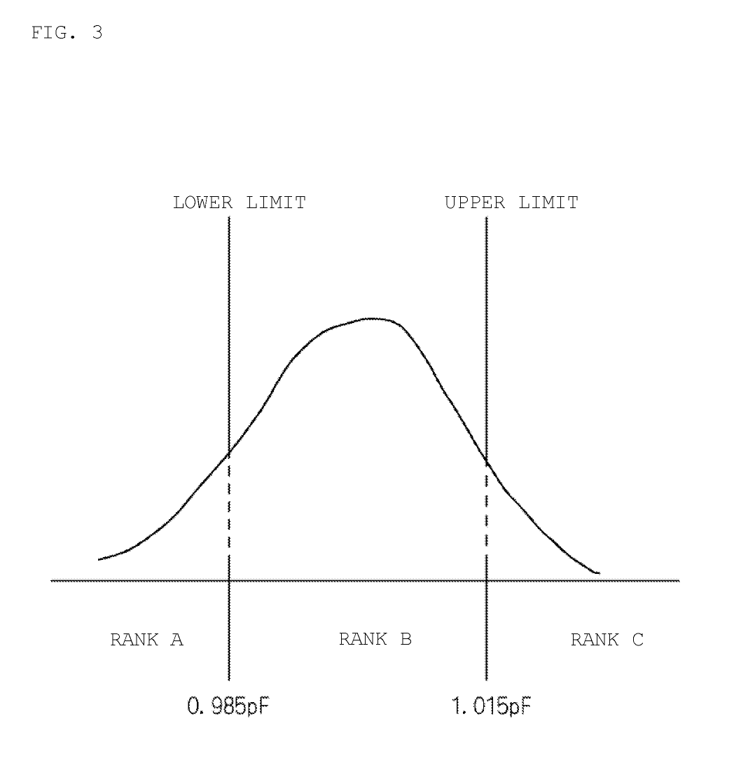

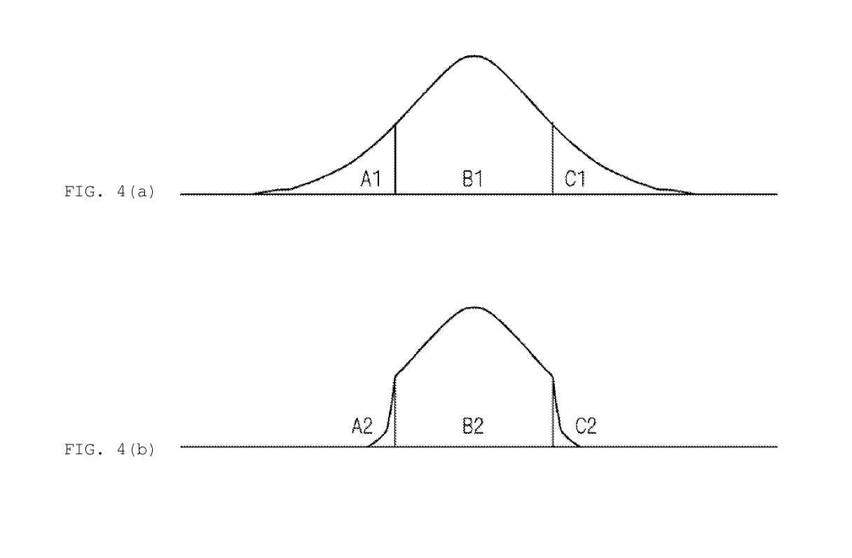

FIGS. 4(a) and 4(b) are graphs for illustrating a method for the product stratification device according to the first exemplary embodiment to calculate the estimation number of the products 10 belonging to each of the ranks. As shown in FIG. 4(a), first, the products 10 whose total number is denoted as SUM1 are stratified into the three ranks: the rank A, the rank B, and the rank C, and respective numbers A1, B1, and C1 of the products 10 belonging to the rank A, the rank B, and the rank C are determined.

Then, re-stratification is performed on the products 10 belonging to the rank B, causing some of the products 10 to be determined to belong to the rank A or the rank C. Specifically, as shown in FIG. 4(b), the number of the products 10 belonging to the rank B results in B2, and an increment number A2 of the products 10 belonging to the rank A and an increment number C2 of the products 10 belonging to the rank C can be individually determined.

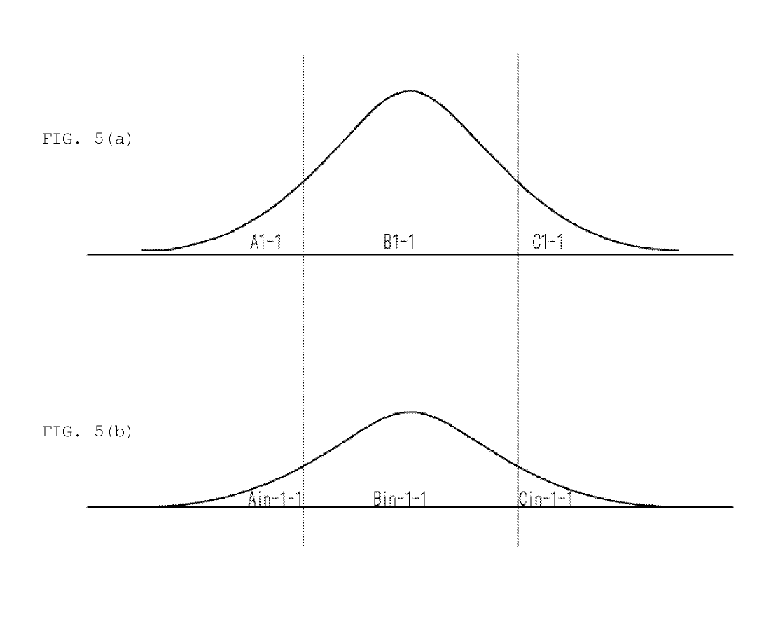

FIGS. 5(a) and 5(b) are schematic graphs showing an image of re-stratification under the identical standards performed by the product stratification device according to the first exemplary embodiment. As shown in FIG. 5(a), for a predetermined item, the number of the products 10 determined to belong to the rank A is denoted as A1-1, the number of the products 10 determined to belong to the rank B is denoted as B1-1, and the number of the products 10 determined to belong to the rank C is denoted as C1-1.

In a case where re-stratification is performed on the products 10 belonging to the rank B, that is, the products 10 determined to be non-defectives, the number of the products 10 belonging to each of the ranks is calculated assuming that a probability distribution is identical to the probability distribution of FIG. 5(a). More specifically, as shown in FIG. 5(b), assuming that the probability distribution having an average and a standard deviation respectively identical to the average and the standard deviation of the probability distribution of FIG. 5(a) is applied, a number Aᵢₙ-1-1 of the products 10 determined to belong to the rank A, a number Bᵢₙ-1-1 of the products 10 determined to belong to the rank B, and a number Cᵢₙ-1-1 of the products 10 determined to belong to the rank C are individually calculated. The number Bᵢₙ-1-1 calculated of the products 10 determined to belong to the rank B is a total non-defective number G_{TOTAL}.

For example, for an item 1, in a case where the number B1-1 corresponding to the number of non-defectives is 3011, the number A1-1 corresponding to the number of lower-side defectives is 123, the number C1-1 corresponding to the number of upper-side defectives is 252, and the total non-defective number G_{TOTAL} is 2780, the number Aᵢₙ-1-1 of the products 10 that belong to the rank A in a case where re-stratification is performed can be determined from (A₁₋₁× G_{TOTAL}/B₁₋₁=123×2780/3011=113.5636), and the number Cᵢₙ-1-1 of the products 10 that belong to the rank C in a case where re-stratification is performed can be calculated from (C₁₋₁× G_{TOTAL}/B₁₋₁=252×2780/3011=232.6669). Note that a number AC1-ᵢₙ-2 of the products 10 determined to be defectives in a case where re-stratification is performed on the products 10 that belong to the rank B after stratification is 48.

Similarly, for an item 2, in a case where a number B2-1 corresponding to the number of non-defectives is 2998, a number A2-1 corresponding to the number of lower-side defectives is 156, a number C2-1 corresponding to the number of upper-side defectives is 232, and the total non-defective number G_{TOTAL} is 2780, a number Aᵢₙ-2-1 of the products 10 that belong to the rank A in a case where re-stratification is performed can be calculated from (A₂₋₁×G_{TOTAL}/B₂₋₁=156×2780/1998=144.6564), and a number Cᵢₙ-2-1 of the products 10 that belong to the rank C in a case where re-stratification is performed can be calculated from (C₂₋₁×G_{TOTAL}/B₂₋₁=232×2780/2998=215.1301). Note that a number AC2-ᵢₙ-2 of the products 10 determined to be defectives in a case where re-stratification is performed on the products 10 that belong to the rank B after stratification is 53.

Similarly, for an item 3, in a case where a number B3-1 corresponding to the number of non-defectives is 2983, a number A3-1 corresponding to the number of lower-side defectives is 231, a number C3-1 corresponding to the number of upper-side defectives is 172, and the total non-defective number G_{TOTAL} is 2780, a number Aᵢₙ-3-1 of the products 10 that belong to the rank A in a case where re-stratification is performed can be calculated from (A₃₋₁× G_{TOTAL}/B₃₋₁=231×2780/2983=215.2799), and a number Cᵢₙ-3-1 of the products 10 that belong to the rank C in a case where re-stratification is performed can be calculated from (C₃₋₁× G_{TOTAL}/B₃₋₁=172×2780/2983=160.2950). Note that a number AC3-ᵢₙ-2 of the products 10 determined to be defectives in a case where re-stratification is performed on the products 10 that belong to the rank B after stratification is 36.

Returning to FIG. 2, a variation calculating module 7 (i.e., a variation calculator) is configured to calculate, for each of the items, the measured value variation of the products 10 based on the estimation number estimated for each of the items. For the above-described example, a method of calculating the measured value variation for each of the item 1, the item 2, and the item 3 from the estimation number will be described below. First, in FIG. 5(a), the total number SUM1 of the products 10 is the sum total of the number A1-1 of the products 10 determined to belong to the rank A, the number B1-1 of the products 10 determined to belong to the rank B, and the number C1-1 of the products 10 determined to belong to the rank C; accordingly, the total number SUM1 is 3386 in the above-described example.

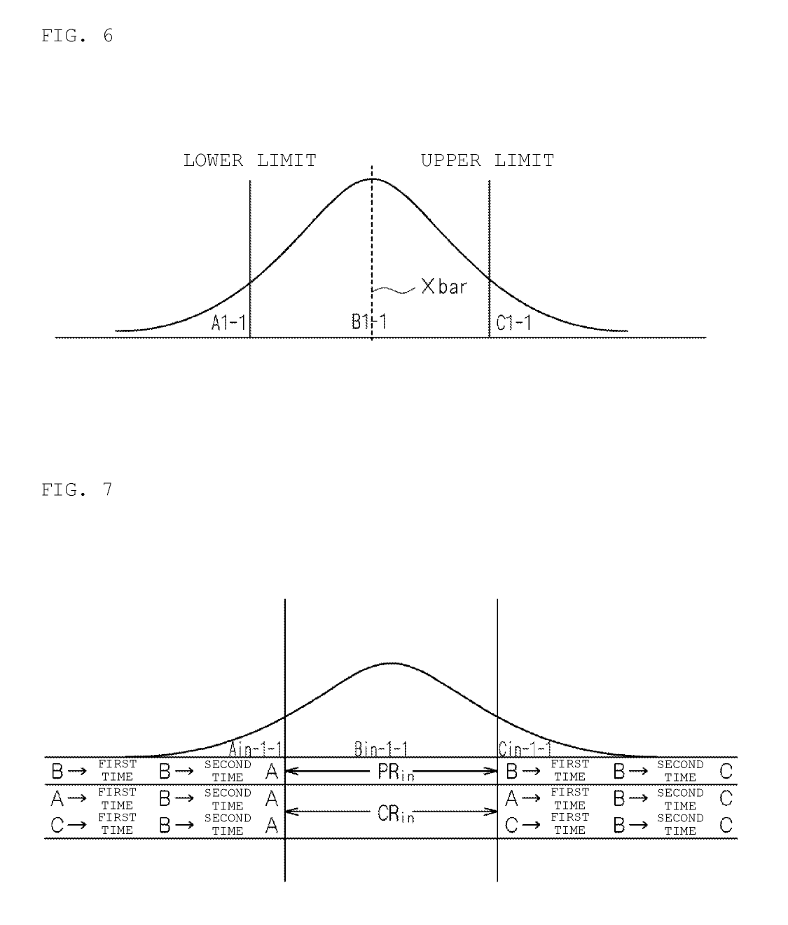

FIG. 6 is a graph for illustrating a probability distribution in stratification under the identical standards performed by the product stratification device according to the first exemplary embodiment. As shown in FIG. 6, assuming that the number of the products 10 determined to belong to the rank B for non-defectives is B1-1, the median point of the number B1-1 is an average X_{bar} of the characteristic values.

With the upper limit and the lower limit of the inspection standard respectively identical to the upper limit and the lower limit of the product standard, the lower limit and the upper limit of the product standard are respectively expressed by X_{bar} (the average of the characteristic values)+x1×σ_{TV} and X_{bar} (the average of the characteristic values)+x2×σ_{TV}, where σ_{TV} represents the standard deviation for variation of all the products.

The lower limit of the product standard is a cumulative probability point corresponding to the number A1-1 in the total number SUM1 of the products 10 and the upper limit of the product standard is a cumulative probability point corresponding to the number (A₁₋₁+B₁₋₁) in the total number SUM1 of the products 10, thus allowing x1 and x2 to be individually determined from an inverse of the cumulative distribution function of the standard normal distribution.

Furthermore, the average X_{bar} of the characteristic values is represented by one of (the lower limit of the product standard−x1×σ_{TV}) and (the upper limit of the product standard−x2×σ_{TV}), thus allowing σ_{TV} to be determined from simplified (Equation 3).

[Math. 3]

σ_{TV}=(Upper limit−Lower limit)/(x2−x1) (Equation 3)

Accordingly, the average X_{bar} of the characteristic values can be determined from (Equation 4), and the products 10 belonging to the rank B, that is, the products 10 determined to be non-defectives can be re-stratified.

[Math. 4]

X_{bar}=Lower limit−x1×σ_{TV} (Equation 4)

FIG. 7 is a graph for illustrating a probability distribution in re-stratification performed by the product stratification device according to the first exemplary embodiment. As shown in FIG. 7, re-stratification is performed with the number B1-1 of the products 10 determined to be non-defectives in the first stratification set as a total number SUM2 for re-stratification. Assuming that a probability distribution is identical to the probability distribution in the first stratification, that is, an average and a standard deviation are respectively identical to the average and the standard deviation of the probability distribution in the first stratification, the number (total non-defective number) of the products 10 belonging to the rank B for non-defectives is denoted as Bᵢₙ-1-1.

With a probability that a non-defective is determined to be a defective in re-stratification, that is, a producer's risk (probability), denoted as PRᵢₙ and a probability that a defective is determined to be a non-defective in the first stratification and determined to be a defective in re-stratification, that is, a consumer's risk (probability), denoted as CRᵢₙ, the number of defectives in re-stratification can be estimated to be a value obtained by multiplication of the total number SUM2 by a probability (PRᵢₙ+CRᵢₙ).

Alternatively, as in the above-described example, for the item 1 as an example, the number AC1-ᵢₙ-2 of the products 10 determined to be defectives in a case where re-stratification is performed on the products 10 that belong to the rank B after stratification is already determined to be 48; thus, measured value variation σ_{GRR1} in which a value obtained by multiplication of the total number SUM2 by the probability (PRᵢₙ+CRᵢₙ) is equal to the number AC1-ᵢₙ-2 may be derived. Measured value variation σ_{GRR2} and measured value variation σ_{GRR3} are respectively derived for the item 2 and the item 3 in the same manner, thus allowing the measured value variation for each of the items to be determined.

(Table 1) shows the process of deriving the measured value variation σ_{GRR1} for the item 1 in the above-described example. In (Table 1), Xₜₐₗ₂ represents a value obtained by multiplication of the total number SUM2 by the sum of the producer's risk (probability) PRᵢₙ and the consumer's risk (probability) CRᵢₙ, and Xₜₐₗ₁ represents the number AC1-ᵢₙ-2 of the products 10 determined to be defectives in a case where re-stratification is performed on the products 10 that belong to the rank B after stratification.

TABLE 1

| Repetition | | | | | |
|---|---|---|---|---|---|
| number | CRin | PRin | Xtal2 | Xtal1 | σ_{GRR1} |
| 1 | 0.00550 | 0.00692 | 38.82222 | 48 | 0.92632 |
| 2 | 0.00919 | 0.01432 | 73.52045 | 48 | 1.76001 |
| 3 | 0.00550 | 0.00692 | 38.82222 | 48 | 0.92632 |
| 4 | 0.00654 | 0.00867 | 47.52768 | 48 | 1.13474 |
| 5 | 0.00750 | 0.01048 | 56.21486 | 48 | 1.34316 |
| 6 | 0.00654 | 0.00867 | 47.52768 | 48 | 1.13474 |
| 7 | 0.00678 | 0.00911 | 49.70132 | 48 | 1.18685 |
| 8 | 0.00654 | 0.00867 | 47.52768 | 48 | 1.13474 |
| 9 | 0.00660 | 0.00878 | 48.07120 | 48 | 1.14777 |
| 10 | 0.00654 | 0.00867 | 47.52768 | 48 | 1.13474 |
| 11 | 0.00655 | 0.00869 | 47.66357 | 48 | 1.13800 |
| 12 | 0.00657 | 0.00872 | 47.79945 | 48 | 1.14126 |
| 13 | 0.00658 | 0.00875 | 47.93533 | 48 | 1.14451 |
| 14 | 0.00660 | 0.00878 | 48.07120 | 48 | 1.14777 |
| 15 | 0.00658 | 0.00875 | 47.93533 | 48 | 1.14451 |
| 16 | 0.00659 | 0.00876 | 47.96930 | 48 | 1.14533 |
| 17 | 0.00659 | 0.00876 | 48.00327 | 48 | 1.14614 |

Similarly, (Table 2) shows the process of deriving the measured value variation σ_{GRR2} for the item 2 in the above-described example, and (Table 3) shows the process of deriving the measured value variation σ_{GRR3} for the item 3 in the above-described example. In (Table 2) and (Table 3), Xₜₐₗ₁ represents the number AC2-ᵢₙ-2 and the number AC3-ᵢₙ-2 of the products 10 determined to be defectives in a case where re-stratification is performed on the products 10 that belong to the rank B after stratification.

TABLE 2

| Repetition | | | | | |
|---|---|---|---|---|---|
| number | CRin | PRin | Xtal2 | Xtal1 | σ_{GRR2} |
| 1 | 0.00571 | 0.00718 | 40.45657 | 53 | 3.46881 |
| 2 | 0.00954 | 0.01486 | 76.61892 | 53 | 6.59073 |
| 3 | 0.00571 | 0.00718 | 40.45657 | 53 | 3.46881 |
| 4 | 0.00678 | 0.00899 | 49.52895 | 53 | 4.24929 |
| 5 | 0.00778 | 0.01088 | 58.58253 | 53 | 5.02977 |
| 6 | 0.00678 | 0.00899 | 49.52895 | 53 | 4.24929 |
| 7 | 0.00704 | 0.00946 | 51.79425 | 53 | 4.44441 |
| 8 | 0.00729 | 0.00993 | 54.05832 | 53 | 4.63953 |
| 9 | 0.00704 | 0.00946 | 51.79425 | 53 | 4.44441 |
| 10 | 0.00710 | 0.00957 | 52.36038 | 53 | 4.49319 |
| 11 | 0.00717 | 0.00969 | 52.92644 | 53 | 4.54197 |
| 12 | 0.00723 | 0.00981 | 53.49242 | 53 | 4.59075 |
| 13 | 0.00717 | 0.00969 | 52.92644 | 53 | 4.54197 |
| 14 | 0.00718 | 0.00972 | 53.06794 | 53 | 4.55417 |
| 15 | 0.00717 | 0.00969 | 52.92644 | 53 | 4.54197 |
| 16 | 0.00717 | 0.00970 | 52.96182 | 53 | 4.54502 |
| 17 | 0.00717 | 0.00971 | 52.99719 | 53 | 4.54807 |
| 18 | 0.00718 | 0.00971 | 53.03257 | 53 | 4.55112 |

TABLE 3

| Repetition | | | | | |
|---|---|---|---|---|---|
| number | CRin | PRin | Xtal2 | Xtal1 | σ_{GRR3} |
| 1 | 0.00590 | 0.00740 | 41.97869 | 36 | 1.79123 |
| 2 | 0.00063 | 0.00067 | 4.09568 | 36 | 0.17912 |
| 3 | 0.00208 | 0.00224 | 13.65619 | 36 | 0.58215 |
| 4 | 0.00343 | 0.00389 | 23.10657 | 36 | 0.98518 |
| 5 | 0.00470 | 0.00561 | 32.54853 | 36 | 1.38821 |
| 6 | 0.00590 | 0.00740 | 41.97869 | 36 | 1.79123 |
| 7 | 0.00470 | 0.00561 | 32.54853 | 36 | 1.38821 |
| 8 | 0.00501 | 0.00605 | 34.90731 | 36 | 1.48896 |
| 9 | 0.00531 | 0.00650 | 37.26530 | 36 | 1.58972 |
| 10 | 0.00501 | 0.00605 | 34.90731 | 36 | 1.48896 |
| 11 | 0.00509 | 0.00616 | 35.49688 | 36 | 1.51415 |
| 12 | 0.00516 | 0.00627 | 36.08641 | 36 | 1.53934 |
| 13 | 0.00509 | 0.00616 | 35.49688 | 36 | 1.51415 |
| 14 | 0.00511 | 0.00619 | 35.64427 | 36 | 1.52045 |
| 15 | 0.00512 | 0.00622 | 35.79165 | 36 | 1.52675 |
| 16 | 0.00514 | 0.00625 | 35.93903 | 36 | 1.53305 |
| 17 | 0.00516 | 0.00627 | 36.08641 | 36 | 1.53934 |
| 18 | 0.00514 | 0.00625 | 35.93903 | 36 | 1.53305 |
| 19 | 0.00515 | 0.00625 | 35.97588 | 36 | 1.53462 |
| 20 | 0.00515 | 0.00626 | 36.01272 | 36 | 1.53619 |

Such a process allows distribution data for the plurality of items in the first stratification to be estimated only by stratifying the products into the three ranks: the rank A, the rank B, and the rank C in the first stratification and re-stratifying the products belonging to the rank B for non-defectives, thus allowing the measured value variations σ_{GRR1}, σ_{GRR2}, and σ_{GRR3} for each of the items to be derived.

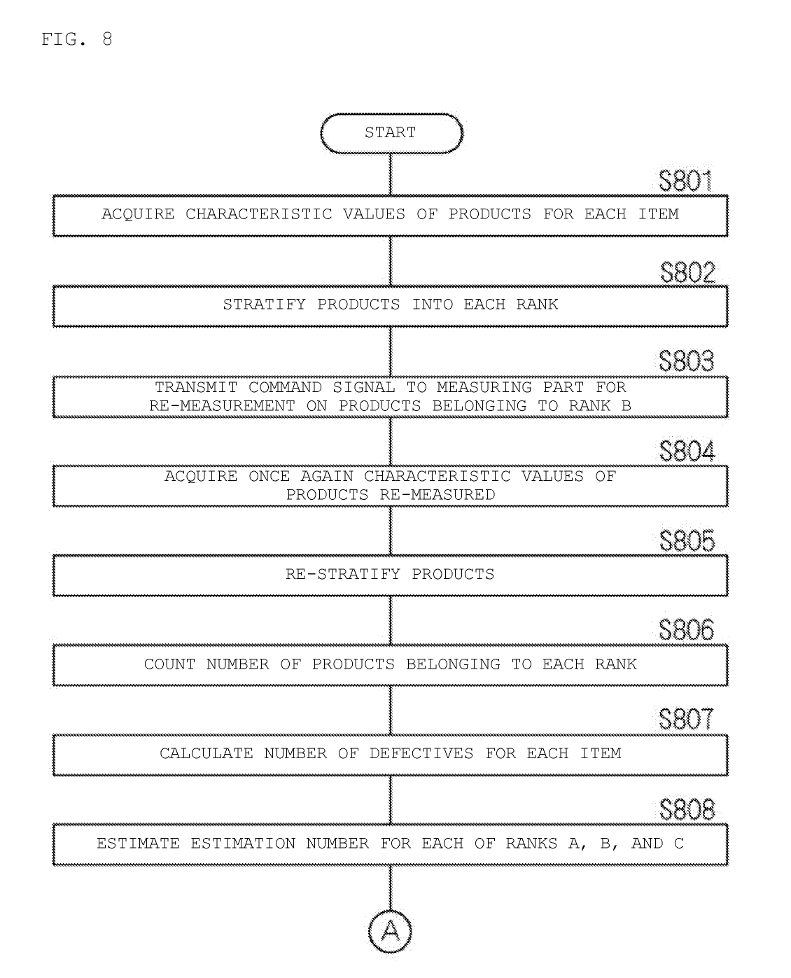

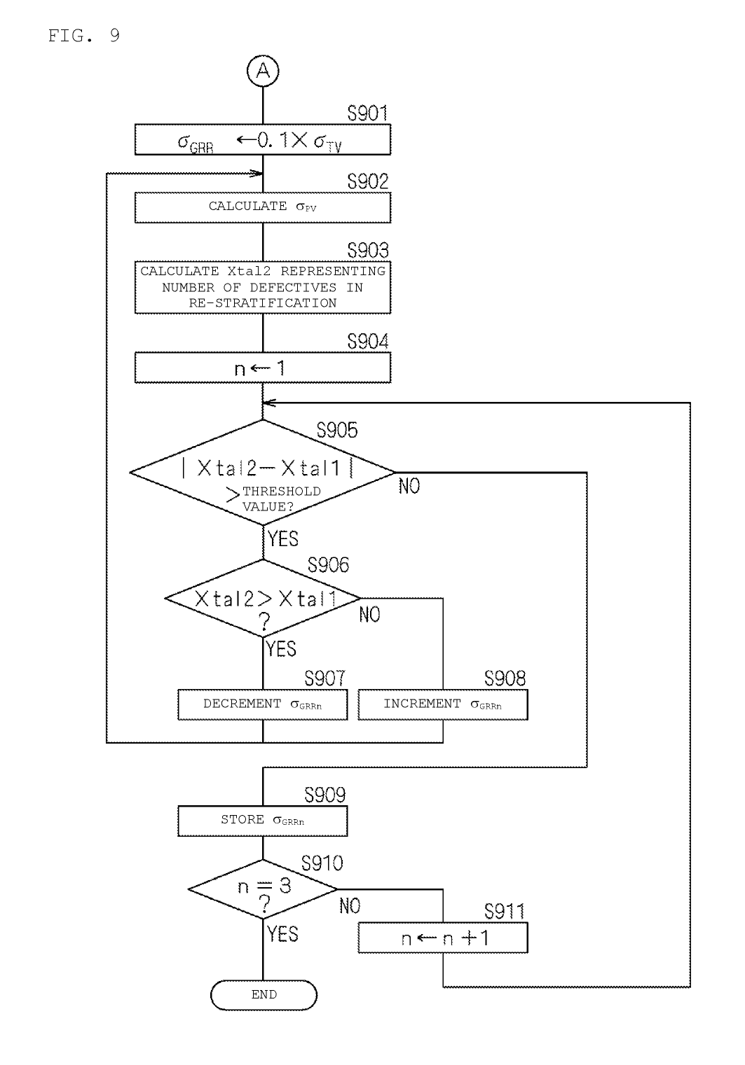

FIG. 8 and FIG. 9 are flowcharts showing the processing procedure in which the product stratification device calculates the measured value variation σ_{GRR} according to the first exemplary embodiment. In general, as noted above, the CPU 21 is configured to perform the exemplary algorithms described herein. Thus, according to the aspect shown in FIG. 8, the CPU 21 of the operation processing part 2 of the product stratification device according to the first embodiment acquires, via the measurement interface 27, the characteristic values of the products 10 for each of the items measured by the measuring part 1 (step S801), and stratifies the products 10 into the rank A, the rank B, and the rank C shown in FIG. 3 based on the characteristic values acquired of the products 10 for each of the items (step S802).

The CPU 21 transmits a command signal to the measuring part 1 to cause the measuring part 1 to re-measure, for each of the items, the characteristic values of the products 10 that belong to the rank B as a result of stratification (step S803). The measuring part 1 that has received the command signal re-measures, for each of the items, the characteristic values of the products 10 that belong to the rank B as a result of stratification.

The CPU 21 acquires once again the characteristic values re-measured of the products 10 for each of the items (step S804); re-stratifies the products 10 into the plurality of ranks based on the characteristic values acquired once again for each of the items (step S805); counts, for each of the items, the number of the products 10 that belong to each of the ranks as a result of re-stratification (step S806); and calculates the number of defectives for each of the items, such as the number AC1-ᵢₙ-2 of defectives for the item 1, the number AC2-ᵢₙ-2 of defectives for the item 2, and the number AC3-ᵢₙ-2 of defectives for the item 3 (step S807).

The CPU 21 estimates respective estimation numbers of the products 10 that belong to the rank A, the rank B, and the rank C as a result of re-stratification assuming that an average and a standard deviation are respectively identical to the average and the standard deviation in the first stratification (step S808) and calculates the total characteristic value variation σ_{TV} of the products 10.

In FIG. 9, the CPU 21 sets the measured value variation σ_{GRR} (the measured value variation σ_{GRR1} for the item 1, the measured value variation σ_{GRR2} for the item 2, the measured value variation σ_{GRR3} for the item 3) to 0.1× σ_{TV} (step S901) and calculates the characteristic value variation am/of the products (step S902). The characteristic value variation σ_{PV} can be calculated as the square root of (σ_{TV2}+σ_{GRR2}).

Next, with the probability PRᵢₙ that a non-defective is determined to be a defective in re-stratification and the probability CRᵢₙ that a defective is determined to be a non-defective in the first stratification and determined to be a defective in re-stratification, the CPU 21 calculates, for each of the items, the number Xₜₐₗ₂ of defectives in re-stratification (step S903).

The CPU 21 selects an item n=1 (step S904) and determines whether the absolute value of a difference between Xₜₐₗ₂ calculated and Xₜₐₗ₁=ACn-ᵢₙ-2 corresponding to the number of defectives is greater than a predetermined threshold value (step S905). In a case where the CPU 21 determines that the difference is greater than the predetermined threshold value (YES in step S905), the CPU 21 determines whether Xₜₐₗ₂ calculated is greater than the number Xₜₐₗ₁ of defectives (step S906).

In a case where the CPU 21 determines that Xₜₐₗ₂ calculated is greater than the number Xₜₐₗ₁ of defectives (YES in step S906), the CPU 21 decrements the measured value variation σ_{GRRn} by a predetermined value (step S907) and returns to step S902 for a repeat of the above-described process. In a case where the CPU 21 determines that Xₜₐₗ₂ calculated is less than the number Xₜₐₗ₁ of defectives (NO in step S906), the CPU 21 increments the measured value variation σ_{GRRn} by the predetermined value (step S908) and returns to step S902 for a repeat of the above-described process.

In a case where the CPU 21 determines that the difference is equal to or less than the predetermined threshold value (NO in step S905), the CPU 21 stores the present measured value variation σ_{GRRn} for the item n (step S909) and determines whether n is equal to 3 (step S910). In a case where the CPU 21 determines that n is not equal to 3 (NO in step S910), the CPU 21 increments n by 1 (step S911) and returns to step S905 for a repeat of the above-described process. In a case where the CPU 21 determines that n is equal to 3 (YES in step S910), the CPU 21 terminates the process.

As described above, the measured value variations σ_{GRR1}, σ_{GRR2}, and σ_{GRR3} can be derived from the probability distribution determined, for each of the items, from the average and the standard deviation in the first stratification, thus allowing the operation processing time to be shortened.

As described above, the product stratification device according to the first embodiment is capable of estimating the probability distribution for each of the items by performing re-stratification only on the products 10 belonging to the rank B for non-defectives, thus allowing the consumer's risk and the producer's risk to be calculated for each of the items. Therefore, the estimation number in a case where re-stratification is performed on the products belonging to the rank B for non-defectives is estimated for each of the items, and the measured value variation of the products is calculated for each of the items based on the estimation number, thus allowing the measured value variation σ_{GRR} to be calculated from the probability distribution for the products determined in the first stratification. Consequently, the overall measurement workload can be reduced, and a reduction in the production time and a decrease in the production cost can be achieved.

### Second Embodiment

A product stratification device according to a second exemplary embodiment has the same example configuration and function as the example configuration and function of the first embodiment illustrated in FIG. 1 and FIG. 2, and the same reference symbols are used; thus, a detailed description of the product stratification device will be omitted. The second embodiment is different from the first embodiment in that the characteristic values of the products 10 belonging to the rank A and the rank C are re-measured, the products are re-stratified, for each of the items, into the predetermined plurality of ranks based on the characteristic values re-measured, and then the measured value variation σ_{GRR} is calculated.

The stratifying module 3 illustrated in FIG. 2 is configured to stratify the products 10 into the predetermined plurality of ranks A, B, and C shown in FIG. 3, based on the plurality of characteristic values measured by the measuring part 1. The re-stratifying module 5 is configured to cause the measuring part 1 to re-measure the plurality of characteristic values of the products 10 that belong to the rank A and the rank C of the predetermined plurality of ranks as a result of stratification performed by the stratifying module 3, and re-stratify, based on the plurality of characteristic values re-measured, the products 10 into ranks defined based on the inspection standard applied to the stratifying module 3.

The deemed standard deviation calculating module 4 is configured to calculate, for each of the items, an average of the characteristic values measured and a deemed standard deviation corresponding to a standard deviation for variation in the characteristic values.

Note that the deemed standard deviation calculating module 4 is capable of calculating not only the deemed standard deviation, but also the average of the characteristic values measured of the products 10.

The re-stratifying module 5 is configured to perform re-stratification on the products 10 belonging to the rank A and the rank C. A rank-by-rank estimation number calculating module 6 is configured to estimate, for each of the items, an estimation number of the products 10 that belong to each of the ranks in a case where at least one time of re-stratification is performed, based on the probability distribution for the average and the deemed standard deviation for the products 10 calculated for each of the items.

In the second embodiment, re-stratification is performed on the products 10 belonging to the rank A and the rank C, and the measured value variation σ_{GRR} is calculated for each of the items. Specifically, in a case where the proportion of non-defectives is relatively high, re-stratification on the non-defectives for calculating the measured value variation σ_{GRR} requires a large amount of operation time. Thus, re-stratification is performed on the products 10 belonging to the rank A and the rank C assuming that a probability distribution is identical to the probability distribution for each of the items resulting from the first stratification, that is, an average and a standard deviation are respectively identical to the average and the standard deviation of the characteristic values, thus significantly reducing an operation processing load.

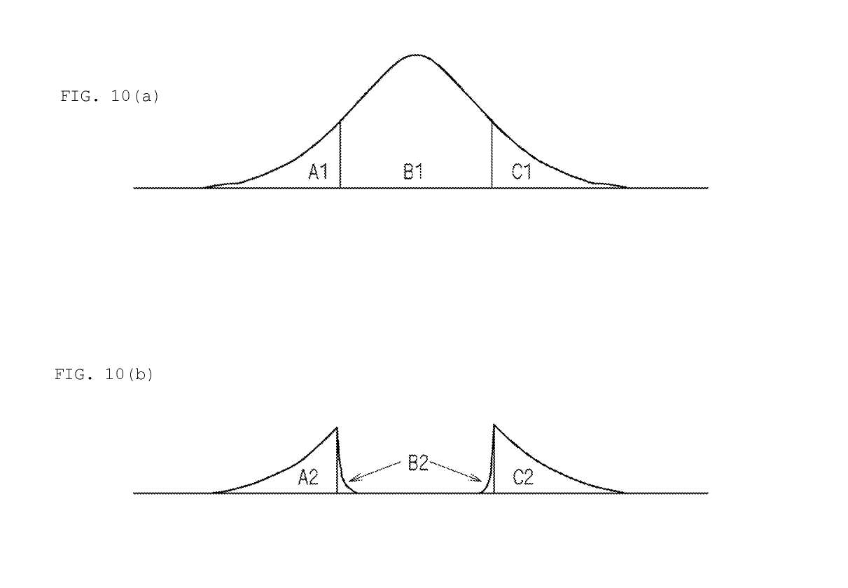

FIGS. 10(a) and 10(b) are graphs for illustrating a method for the product stratification device according to the second exemplary embodiment to calculate the estimation number of the products 10 belonging to each of the ranks. As shown in FIG. 10(a), first, the products 10 whose total number is denoted as SUM1 are stratified into the three ranks: the rank A, the rank B, and the rank C, and respective numbers A1, B1, and C1 of the products 10 belonging to the rank A, the rank B, and the rank C are individually determined.

Then, re-stratification is performed on the products 10 belonging to the rank A and the rank C, causing some of the products 10 to be determined to belong to the rank B. Specifically, as shown in FIG. 10(b), the number of the products 10 belonging to the rank A results in A2 and the number of the products 10 belonging to the rank C results in C2, and an increment number B2 of the products 10 belonging to the rank B can be determined.

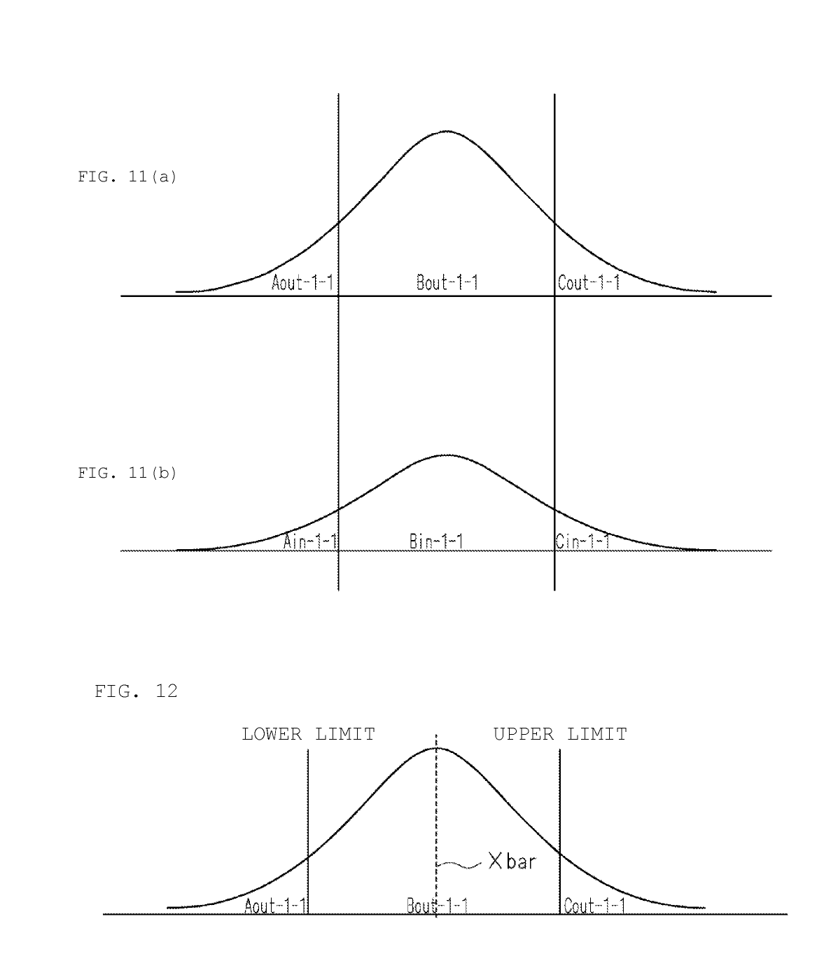

FIGS. 11(a) and 11(b) are schematic graphs showing an image of re-stratification under the identical standards performed by the product stratification device according to the second exemplary embodiment. As shown in FIG. 11(a), for a predetermined item, the number of the products 10 determined to belong to the rank A is denoted as A_{OUT}-1-1, the number of the products 10 determined to belong to the rank B is denoted as B_{OUT}-1-1, and the number of the products 10 determined to belong to the rank C is denoted as C_{OUT}-1-1.

In a case where re-stratification is performed on the products 10 belonging to one of the rank A and the rank C, that is, the products 10 determined to be non-defectives, the number of the products 10 belonging to each of the ranks is calculated assuming that a probability distribution is identical to the probability distribution of FIG. 11(a). Specifically, as shown in FIG. 11(b), assuming that the probability distribution having an average and a standard deviation respectively identical to the average and the standard deviation of the probability distribution of FIG. 10(a) is applied, a number Aᵢₙ-1-1 of the products 10 determined to belong to the rank A, a number Bᵢₙ-1-1 of the products 10 determined to belong to the rank B, and a number Cᵢₙ-1-1 of the products 10 determined to belong to the rank C are individually calculated.

For example, for the item 1, in a case where the number B_{OUT}-1-1 corresponding to the number of non-defectives is 3046, the number A_{OUT}-1-1 corresponding to the number of lower-side defectives is 598, the number C_{OUT}-1-1 corresponding to the number of upper-side defectives is 942, and the total non-defective number G_{TOTAL} is 1718, the number Bᵢₙ-1-1 of the products 10 determined to belong to the rank B for non-defectives, but determined to be defectives for the other items can be determined from (B_{OUT-1-1}−G_{TOTAL}=3046−1718=1328).

The number Aᵢₙ-1-1 of the products 10 determined to belong to the rank A and also determined to be defectives for the other items can be calculated from (Bᵢₙ₋₁₋₁× A_{OUT-1-1}/B_{OUT-1-1}=1328×598/3046=260.7170), and the number Cᵢₙ-1-1 of the products 10 determined to belong to the rank C and also determined to be defectives for the other items can be calculated from (Bᵢₙ₋₁₋₁×C_{OUT-1-1}/B_{OUT-1-1}=1328×942/3046=410.6947). Note that a number ACᵢₙ-_{OUT}-1-2 of the products 10 determined to be defectives as a result of re-stratification performed on the products 10 determined to be defectives for any of the items after stratification is 1263.

Similarly, for the item 2, in a case where a number B_{OUT}-2-1 corresponding to the number of non-defectives is 3051, a number A_{OUT}-2-1 corresponding to the number of lower-side defectives is 562, a number C_{OUT}-2-1 corresponding to the number of upper-side defectives is 973, a number Bᵢₙ-2-1 of the products 10 determined to belong to the rank B for non-defectives, but determined to be defectives for the other items can be calculated from (B_{OUT-2-1}−G_{TOTAL}=3051−1718=1333).

Furthermore, a number Aᵢₙ-2-1 of the products 10 determined to belong to the rank A and also determined to be defectives for the other items can be calculated from (Bᵢₙ₋₂₋₁×A_{OUT-2-1}/B_{OUT-2-1}=1333×562/3051=245.5411), and a number Cᵢₙ-2-1 of the products 10 determined to belong to the rank C and also determined to be defectives for the other items can be calculated from (Bᵢₙ₋₂₋₁× C_{OUT-2-1}/B_{OUT-2-1}=1333×973/3051=425.1095). Note that a number ACᵢₙ-_{OUT}-2-2 of the products 10 determined to be defectives as a result of re-stratification performed on the products 10 determined to be defectives for any of the items after stratification is 1390.

Similarly, for the item 3, in a case where a number B_{OUT}-3-1 corresponding to the number of non-defectives is 3004, a number A_{OUT}-3-1 corresponding to the number of lower-side defectives is 1179, a number C_{OUT}-3-1 corresponding to the number of upper-side defectives is 403, a number Bᵢₙ-3-1 of the products 10 determined to belong to the rank B for non-defectives, but determined to be defectives for the other items can be calculated from (B_{OUT-3-1}−G_{TOTAL}=3004−1718=1286).

Furthermore, a number Aᵢₙ-3-1 of the products 10 determined to belong to the rank A and also determined to be defectives for the other items can be calculated from (Bᵢₙ₋₃₋₁×A_{OUT-3-1}/B_{OUT-3-1}=1286×1179/3004=504.7250), and a number Cᵢₙ-3-1 of the products 10 determined to belong to the rank C and also determined to be defectives for the other items can be calculated from (Bᵢₙ₋₃₋₁×C_{OUT-3-1}/B_{OUT-3-1}=1286×403/3004=172.5226). Note that a number ACᵢₙ-_{OUT}-3-2 of the products 10 determined to be defectives as a result of re-stratification performed on the products 10 determined to be defectives for any of the items after stratification is 1266.

The variation calculating module 7 illustrated in FIG. 2 is configured to calculate, for each of the items, the measured value variation of the products 10 based on the estimation number estimated for each of the items. For the above-described example, a method of calculating the measured value variation for each of the item 1, the item 2, and the item 3 from the estimation number will be described below. First, in FIG. 11(a), the total number SUM1 of the products 10 is the sum total of the number A_{OUT}-1-1 of the products 10 determined to belong to the rank A, the number B_{OUT}-1-1 of the products 10 determined to belong to the rank B, and the number C_{OUT}-1-1 of the products 10 determined to belong to the rank C; accordingly, the total number SUM1 is 4586 in the above-described example.

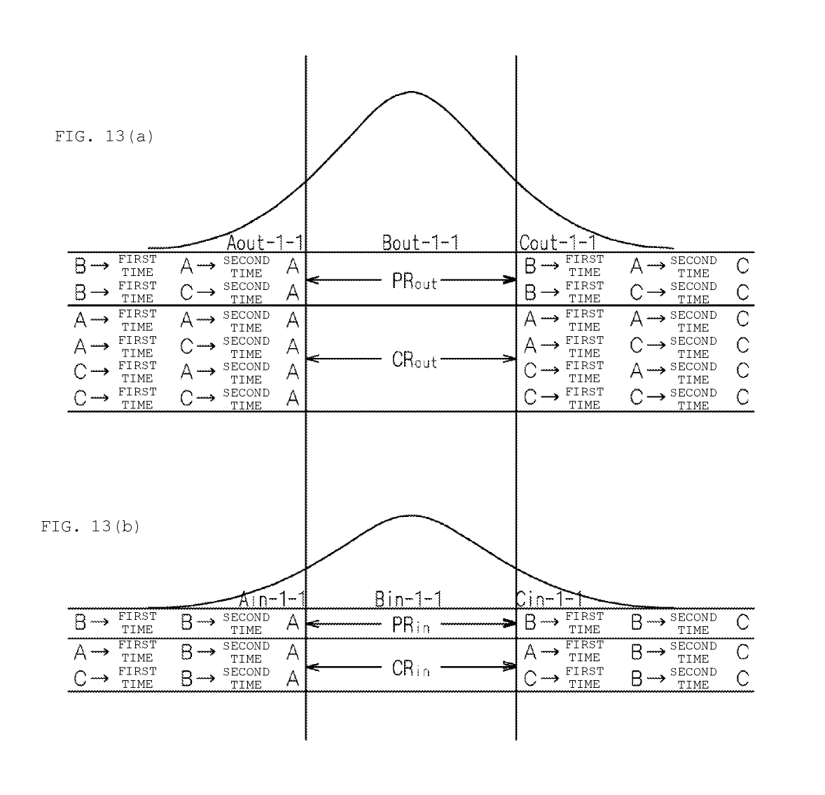

FIG. 12 is a graph for illustrating a probability distribution in stratification under the identical standards performed by the product stratification device according to the second exemplary embodiment. As shown in FIG. 12, assuming that the number of the products 10 determined to belong to the rank B for non-defectives is B_{OUT}-1-1, the median point of the number B_{OUT}-1-1 is an average X_{bar} of the characteristic values.

With the upper limit and the lower limit of the inspection standard respectively identical to the upper limit and the lower limit of the product standard, the lower limit and the upper limit of the product standard are respectively expressed by X_{bar} (the average of the characteristic values)+x1× σ_{TV} and X_{bar} (the average of the characteristic values)+x2× σ_{TV}, where σ_{TV} represents the standard deviation for variation of all the products.

The lower limit of the product standard is a cumulative probability point corresponding to the number A_{OUT}-1-1 in the total number SUM1 of the products 10 and the upper limit of the product standard is a cumulative probability point corresponding to the number (A_{OUT}-1-1+B_{OUT}-1-1) in the total number SUM1 of the products 10, thus allowing x1 and x2 to be individually determined from an inverse of the cumulative distribution function of the standard normal distribution.

Furthermore, the average X_{bar} of the characteristic values is represented by one of (the lower limit of the product standard−x1× σ_{TV}) and (the upper limit of the product standard−x2×σ_{TV}), thus allowing σ_{TV} to be determined from simplified (Equation 5).

[Math. 5]

σ_{TV}=(Upper limit−Lower limit)/(x2−x1) (Equation 5)

Accordingly, the average X_{bar} of the characteristic values can be determined from (Equation 6), and the products 10 belonging to the rank B, that is, the products 10 determined to be non-defectives can be re-stratified.

[Math. 6]

X_{bar}=Lower limit−x1×σ_{TV} (Equation 6)

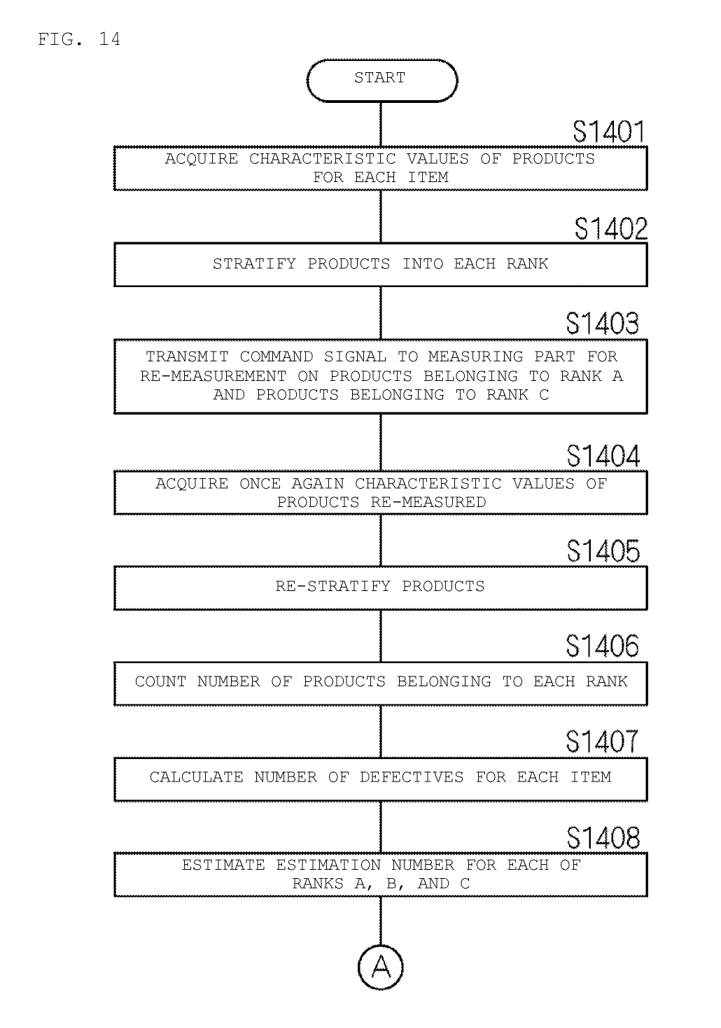

FIGS. 13(a) and 13(b) are graphs for illustrating probability distributions in re-stratification performed by the product stratification device according to the second exemplary embodiment. In FIGS. 13(a) and 13(b), re-stratification is performed on the products 10 denoted as A_{OUT}-1-1 and the products 10 denoted as C_{OUT}-1-1 that are determined to be defectives in the first stratification, and the products 10 denoted as Bᵢₙ-1-1 that are determined to be non-defectives for the item 1, but determined to be defectives for the other items in the first stratification. That is, the second embodiment is different from the first embodiment in that out-of-standard stratification corresponding to re-stratification on defectives, and in-standard stratification corresponding to re-stratification on non-defectives are performed at the same time. In re-stratification, assuming that a probability distribution is identical to the probability distribution in the first stratification, that is, an average and a standard deviation are respectively identical to the average and the standard deviation of the probability distribution in the first stratification, the estimation number is calculated such that the total number SUM2 is equal to (Aᵢₙ₋₁₋₁+B_{in 1-1}+Cᵢₙ₋₁₋₁).

With a probability that a non-defective is determined to be a defective in stratification, that is, a producer's risk (probability), denoted as PR_{OUT}; a producer's risk (probability) that a non-defective is determined to be a defective in re-stratification denoted as Rᵢₙ; a consumer's risk (probability) that a defective is determined to be a non-defective in stratification and determined to be a defective in re-stratification denoted as CRᵢₙ; and a consumer's risk (probability) that a defective is determined to be any of the upper-side defective and the lower-side defective denoted as CR_{OUT}, the number of defectives in re-stratification can be estimated to be the sum of a value obtained by multiplication of the total number SUM1 by the probability (PR_{OUT}+CR_{OUT}) and a value obtained by multiplication of the total number SUM2 by the probability (Rᵢₙ+CRᵢₙ).

Alternatively, as in the above-described example, for the item 1 as an example, the number ACᵢₙ-_{OUT}-1-2 of the products 10 determined to be defectives as a result of re-stratification performed on the products 10 determined to be defectives for any of the items is already determined to be 1263; thus, measured value variation σ_{GRR1} in which the sum of a value obtained by multiplication of the total number SUM1 by the probability (PRₒᵤₜ+CRₒᵤₜ) and a value obtained by multiplication of the total number SUM2 by the probability (PRᵢₙ+CRᵢₙ) is equal to the number ACᵢₙ-_{OUT}-1-2 may be derived. Measured value variation σ_{GRR2} and measured value variation σ_{GRR3} are respectively derived for the item 2 and the item 3 in the same manner, thus allowing the measured value variation for each of the items to be determined.

(Table 4) shows the process of deriving the measured value variation σ_{GRR1} for the item 1 in the above-described example. In (Table 4), Xₜₐₗ₂ represents the sum of the value obtained by multiplication of the total number SUM1 by the probability (PR_{OUT}+CR_{OUT}) and the value obtained by multiplication of the total number SUM2 by the probability (PRᵢₙ+CRᵢₙ), and Xₜₐₗ₁ represents the number ACᵢₙ-_{OUT}-1-2 of the products 10 determined to be defectives as a result of re-stratification performed on the products 10 determined to be defectives for any of the items after stratification.

TABLE 4

| Repetition number | CRᵢₙ | PRᵢₙ | CRₒᵤₜ | PRₒᵤₜ | Xtal2 | Xtal1 | σ_{GRR1} |
|---|---|---|---|---|---|---|---|
| 1 | 0.01303 | 0.01498 | 0.30181 | 0.00601 | 1467.68348 | 1263 | 1.54085 |
| 2 | 0.02307 | 0.03016 | 0.27077 | 0.01182 | 1402.39924 | 1263 | 2.92762 |
| 3 | 0.03138 | 0.04708 | 0.23930 | 0.01806 | 1337.11917 | 1263 | 4.31438 |
| 4 | 0.03777 | 0.06592 | 0.20734 | 0.02479 | 1271.84487 | 1263 | 5.70115 |
| 5 | 0.04191 | 0.08683 | 0.17479 | 0.03229 | 1207.06093 | 1263 | 7.08791 |
| 6 | 0.03777 | 0.06592 | 0.20734 | 0.02479 | 1271.84487 | 1263 | 5.70115 |
| 7 | 0.03903 | 0.07096 | 0.19926 | 0.02657 | 1255.55830 | 1263 | 6.04784 |
| 8 | 0.03777 | 0.06592 | 0.20734 | 0.02479 | 1271.84487 | 1263 | 5.70115 |
| 9 | 0.03809 | 0.06717 | 0.20532 | 0.02523 | 1267.77049 | 1263 | 5.78782 |
| 10 | 0.03841 | 0.06842 | 0.20330 | 0.02567 | 1263.69774 | 1263 | 5.87449 |
| 11 | 0.03873 | 0.06969 | 0.20128 | 0.02612 | 1259.62691 | 1263 | 5.96117 |
| 12 | 0.03841 | 0.06842 | 0.20330 | 0.02567 | 1263.69774 | 1263 | 5.87449 |
| 13 | 0.03849 | 0.06874 | 0.20280 | 0.02578 | 1262.67984 | 1263 | 5.89616 |
| 14 | 0.03841 | 0.06842 | 0.20330 | 0.02567 | 1263.69774 | 1263 | 5.87449 |
| 15 | 0.03843 | 0.06850 | 0.20318 | 0.02570 | 1263.44326 | 1263 | 5.87991 |
| 16 | 0.03845 | 0.06858 | 0.20305 | 0.02573 | 1263.18878 | 1263 | 5.88533 |
| 17 | 0.03847 | 0.06866 | 0.20293 | 0.02576 | 1262.93431 | 1263 | 5.89074 |
| 18 | 0.03845 | 0.06858 | 0.20305 | 0.02573 | 1263.18878 | 1263 | 5.88533 |
| 19 | 0.03846 | 0.06860 | 0.20302 | 0.02573 | 1263.12516 | 1263 | 5.88668 |
| 20 | 0.03846 | 0.06862 | 0.20299 | 0.02574 | 1263.06154 | 1263 | 5.88804 |
| 21 | 0.03847 | 0.06864 | 0.20296 | 0.02575 | 1262.99792 | 1263 | 5.88939 |

Similarly, (Table 5) shows the process of deriving the measured value variation σ_{GRR2} for the item 2 in the above-described example, and (Table 6) shows the process of deriving the measured value variation σ_{GRR3} for the item 3 in the above-described example. In (Table 5) and (Table 6), Xₜₐₗ₁ represents the number ACᵢₙ-_{OUT}-2-2 and the number ACᵢₙ-_{OUT}-3-2 of the products 10 determined to be defectives as a result of re-stratification performed on the products 10 determined to be defectives for any of the items after stratification.

TABLE 5

| Repetition number | CRᵢₙ | PRᵢₙ | CRₒᵤₜ | PRₒᵤₜ | xtal2 | Xtal1 | σ_{GRR2} |
|---|---|---|---|---|---|---|---|
| 1 | 0.01294 | 0.01487 | 0.30096 | 0.00597 | 1463.30987 | 1390 | 5.60860 |
| 2 | 0.02292 | 0.02994 | 0.27014 | 0.01174 | 1398.59311 | 1390 | 10.65635 |
| 3 | 0.03118 | 0.04672 | 0.23890 | 0.01792 | 1333.88259 | 1390 | 15.70409 |
| 4 | 0.02292 | 0.02994 | 0.27014 | 0.01174 | 1398.59311 | 1390 | 10.65635 |
| 5 | 0.02515 | 0.03396 | 0.26237 | 0.01324 | 1382.41680 | 1390 | 11.91828 |
| 6 | 0.02292 | 0.02994 | 0.27014 | 0.01174 | 1398.59311 | 1390 | 10.65635 |
| 7 | 0.02348 | 0.03093 | 0.26820 | 0.01211 | 1394.54907 | 1390 | 10.97183 |
| 8 | 0.02405 | 0.03194 | 0.26626 | 0.01249 | 1390.50501 | 1390 | 11.28732 |
| 9 | 0.02460 | 0.03295 | 0.26432 | 0.01286 | 1386.46093 | 1390 | 11.60280 |
| 10 | 0.02405 | 0.03194 | 0.26626 | 0.01249 | 1390.50501 | 1390 | 11.28732 |
| 11 | 0.02419 | 0.03219 | 0.26578 | 0.01258 | 1389.49399 | 1390 | 11.36619 |
| 12 | 0.02405 | 0.03194 | 0.26626 | 0.01249 | 1390.50501 | 1390 | 11.28732 |
| 13 | 0.02408 | 0.03200 | 0.26614 | 0.01251 | 1390.25226 | 1390 | 11.30703 |
| 14 | 0.02412 | 0.03206 | 0.26602 | 0.01253 | 1389.99950 | 1390 | 11.32675 |
| 15 | 0.02408 | 0.03200 | 0.26614 | 0.01251 | 1390.25226 | 1390 | 11.30703 |
| 16 | 0.02409 | 0.03202 | 0.26611 | 0.01252 | 1390.18907 | 1390 | 11.31196 |
| 17 | 0.02410 | 0.03203 | 0.26608 | 0.01252 | 1390.12588 | 1390 | 11.31689 |
| 18 | 0.02411 | 0.03205 | 0.26605 | 0.01253 | 1390.06269 | 1390 | 11.32182 |
| 19 | 0.02412 | 0.03206 | 0.26602 | 0.01253 | 1389.99950 | 1390 | 11.32675 |

TABLE 6

| Repetition number | CRᵢₙ | PRᵢₙ | CRₒᵤₜ | PRₒᵤₜ | Xtal2 | Xtal1 | σ_{GRR3} |
|---|---|---|---|---|---|---|---|
| 1 | 0.01272 | 0.01447 | 0.31197 | 0.00582 | 1510.79461 | 1266 | 2.79120 |
| 2 | 0.02265 | 0.02904 | 0.28186 | 0.01143 | 1446.51275 | 1266 | 5.30329 |
| 3 | 0.03103 | 0.04516 | 0.25136 | 0.01742 | 1382.21116 | 1266 | 7.81537 |
| 4 | 0.03772 | 0.06300 | 0.22038 | 0.02386 | 1317.86637 | 1266 | 10.32745 |
| 5 | 0.04244 | 0.08270 | 0.18884 | 0.03098 | 1253.80447 | 1266 | 12.83954 |
| 6 | 0.03772 | 0.06300 | 0.22038 | 0.02386 | 1317.86637 | 1266 | 10.32745 |
| 7 | 0.03910 | 0.06776 | 0.21256 | 0.02556 | 1301.79195 | 1266 | 10.95547 |
| 8 | 0.04035 | 0.07262 | 0.20469 | 0.02731 | 1285.74243 | 1266 | 11.58349 |
| 9 | 0.04146 | 0.07761 | 0.19679 | 0.02911 | 1269.73780 | 1266 | 12.21152 |
| 10 | 0.04244 | 0.08270 | 0.18884 | 0.03098 | 1253.80447 | 1266 | 12.83954 |
| 11 | 0.04146 | 0.07761 | 0.19679 | 0.02911 | 1269.73780 | 1266 | 12.21152 |
| 12 | 0.04172 | 0.07887 | 0.19480 | 0.02957 | 1265.74662 | 1266 | 12.36852 |
| 13 | 0.04146 | 0.07761 | 0.19679 | 0.02911 | 1269.73780 | 1266 | 12.21152 |
| 14 | 0.04153 | 0.07792 | 0.19629 | 0.02923 | 1268.73957 | 1266 | 12.25077 |
| 15 | 0.04159 | 0.07824 | 0.19580 | 0.02934 | 1267.74163 | 1266 | 12.29002 |
| 16 | 0.04166 | 0.07855 | 0.19530 | 0.02946 | 1266.74397 | 1266 | 12.32927 |
| 17 | 0.04172 | 0.07887 | 0.19480 | 0.02957 | 1265.74662 | 1266 | 12.36852 |
| 18 | 0.04166 | 0.07855 | 0.19530 | 0.02946 | 1266.74397 | 1266 | 12.32927 |
| 19 | 0.04167 | 0.07863 | 0.19518 | 0.02949 | 1266.49461 | 1266 | 12.33908 |
| 20 | 0.04169 | 0.07871 | 0.19505 | 0.02951 | 1266.24526 | 1266 | 12.34890 |
| 21 | 0.04171 | 0.07879 | 0.19493 | 0.02954 | 1265.99593 | 1266 | 12.35871 |
| 22 | 0.04169 | 0.07871 | 0.19505 | 0.02951 | 1266.24526 | 1266 | 12.34890 |
| 23 | 0.04169 | 0.07873 | 0.19502 | 0.02952 | 1266.18292 | 1266 | 12.35135 |
| 24 | 0.04170 | 0.07875 | 0.19499 | 0.02953 | 1266.12059 | 1266 | 12.35380 |
| 25 | 0.04170 | 0.07877 | 0.19496 | 0.02954 | 1266.05826 | 1266 | 12.35625 |
| 26 | 0.04171 | 0.07879 | 0.19493 | 0.02954 | 1265.99593 | 1266 | 12.35871 |

Such processes allow distribution data for the plurality of items in the first stratification to be estimated only by stratifying the products into the three ranks: the rank A, the rank B, and the rank C in the first stratification and re-stratifying the products belonging to the rank A for defectives and the products belonging to the rank C for defectives, thus allowing the measured value variations σ_{GRR1}, σ_{GRR2}, and σ_{GRR3} for each of the items to be derived.

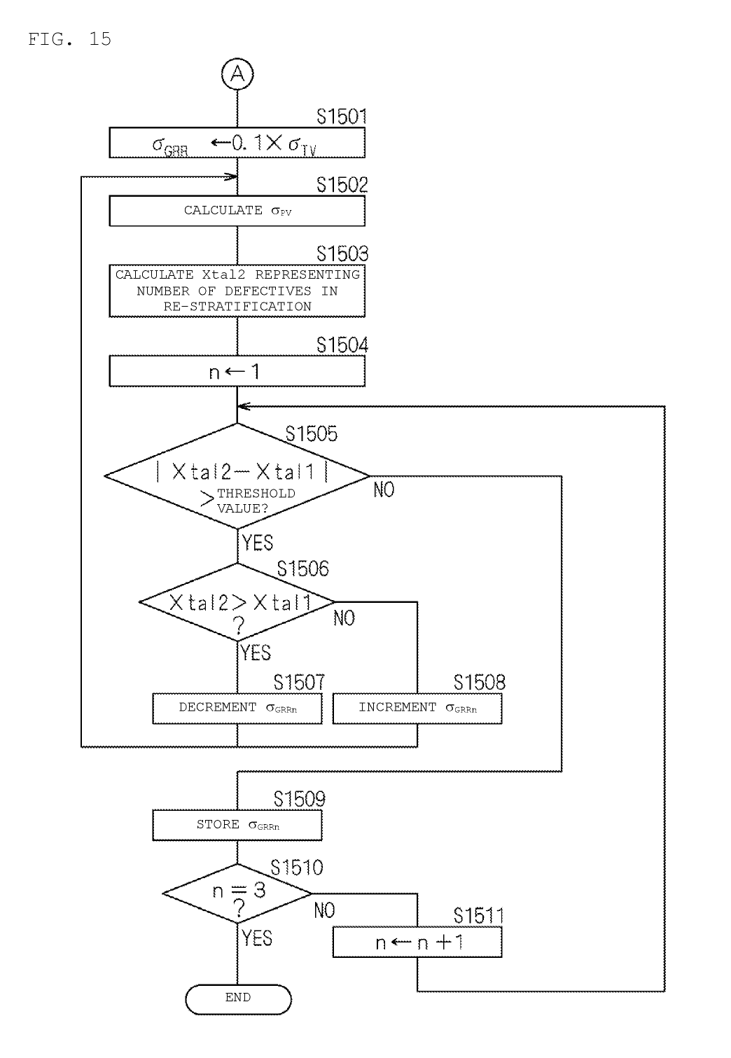

FIG. 14 and FIG. 15 are flowcharts showing the processing procedure in which the product stratification device according to the second exemplary embodiment calculates the measured value variation σ_{GRR}. In FIG. 14, the CPU 21 of the operation processing part 2 of the product stratification device according to the second embodiment acquires, via the measurement interface 27, the characteristic values of the products 10 for each of the items measured by the measuring part 1 (step S1401), and stratifies the products 10 into the rank A, the rank B, and the rank C shown in FIG. 3 based on the characteristic values acquired of the products 10 for each of the items (step S1402).

The CPU 21 transmits a command signal to the measuring part 1 to cause the measuring part 1 to re-measure, for each of the items, the characteristic values of the products 10 that belong to the rank A as a result of stratification and the characteristic values of the products 10 that belong to the rank C as a result of stratification (step S1403). The measuring part 1 that has received the command signal re-measures, for each of the items, the characteristic values of the products 10 that belong to the rank A as a result of stratification and the characteristic values of the products 10 that belong to the rank C as a result of stratification.

The CPU 21 acquires once again the characteristic values re-measured of the products 10 for each of the items (step S1404); re-stratifies the products 10 into the plurality of ranks based on the characteristic values acquired once again for each of the items (step S1405); counts, for each of the items, the number of the products 10 that belong to each of the ranks as a result of re-stratification (step S1406); and calculates the number of defectives for each of the items, such as the number ACᵢₙ-_{OUT}-1-2 of defectives for the item 1, the number ACᵢₙ-_{OUT}-2-2 of defectives for the item 2, and the number ACᵢₙ-_{OUT}-3-2 of defectives for the item 3 (step S1407).

The CPU 21 estimates respective estimation numbers of the products 10 that belong to the rank A, the rank B, and the rank C as a result of re-stratification assuming that an average and a standard deviation are respectively identical to the average and the standard deviation in the first stratification (step S1408) and calculates the total characteristic value variation σ_{TV} of the products 10.

In FIG. 15, the CPU 21 sets the measured value variation σ_{GRR} (the measured value variation σ_{GRR1} for the item 1, the measured value variation σ_{GRR2} for the item 2, the measured value variation σ_{GRR3} for the item 3) to 0.1×σ_{TV} (step S1501) and calculates the characteristic value variation σ_{PV} of the products (step S1502). The characteristic value variation σ_{PV} can be calculated as the square root of (σ_{TV2}+σ_{GRR2}).

Then, with the probability PR_{OUT} that a non-defective is determined to be a defective in stratification; the probability PRᵢₙ that a non-defective is determined to be a defective in re-stratification; the probability CRᵢₙ that a defective is determined to be a non-defective in stratification and determined to be a defective in re-stratification; and the probability CR_{OUT} that a defective is determined to be any of the upper-side defective and the lower-side defective, the CPU 21 calculates, for each of the items, Xₜₐₗ₂ representing the sum of the value obtained by multiplication of the total number SUM1 by the probability (PR_{OUT}+CR_{OUT}) and the value obtained by multiplication of the total number SUM2 by the probability (PRᵢₙ+CRᵢₙ) (step S1503).

The CPU 21 selects an item n=1 (step S1504) and determines whether the absolute value of a difference between Xₜₐₗ₂ calculated and Xₜₐₗ₁=ACᵢₙ-_{OUT}-n−2 corresponding to the number of defectives is greater than a predetermined threshold value (step S1505). In a case where the CPU 21 determines that the difference is greater than the predetermined threshold value (YES in step S1505), the CPU 21 determines whether Xₜₐₗ₂ calculated is greater than the number Xₜₐₗ₁ of defectives (step S1506).

In a case where the CPU 21 determines that Xₜₐₗ₂ calculated is greater than the number Xₜₐₗ₁ of defectives (YES in step S1506), the CPU 21 decrements the measured value variation σ_{GRRn} by a predetermined value (step S1507) and returns to step S1502 for a repeat of the above-described process. In a case where the CPU 21 determines that Xₜₐₗ₂ calculated is less than the number Xₜₐₗ₁ of defectives (NO in step S1506), the CPU 21 increments the measured value variation σ_{GRRn} by the predetermined value (step S1508) and returns to step S1502 for a repeat of the above-described process.

In a case where the CPU 21 determines that the difference is equal to or less than the predetermined threshold value (NO in step S1505), the CPU 21 stores the present measured value variation σ_{GRRn} for the item n (step S1509) and determines whether n is equal to 3 (step S1510). In a case where the CPU 21 determines that n is not equal to 3 (NO in step S1510), the CPU 21 increments n by 1 (step S1511) and returns to step S1505 for a repeat of the above-described process. In a case where the CPU 21 determines that n is equal to 3 (YES in step S1510), the CPU 21 terminates the process.

As described above, the measured value variations σ_{GRR1}, σ_{GRR2}, and σ_{GRR3} can be derived from the probability distribution determined, for each of the items, from the average and the standard deviation in the first stratification, thus allowing the operation processing time to be shortened.

As described above, the product stratification device according to the second embodiment is capable of estimating the probability distribution for each of the items by performing re-stratification only on the products 10 belonging to the rank A for defectives and the products 10 belonging to the rank C for defectives, thus allowing the consumer's risk and the producer's risk to be calculated for each of the items. Therefore, the estimation number in a case where re-stratification is performed on the products 10 belonging to the rank A for defectives and the products 10 belonging to the rank C for defectives is estimated for each of the items, and the measured value variation of the products is calculated for each of the items based on the estimation number, thus allowing the measured value variation σ_{GRR} to be calculated from the probability distribution for the products determined in the first stratification. Consequently, the overall measurement workload can be reduced, and a reduction in the production time and a decrease in the production cost can be achieved.

It is noted that the product stratification device according to the above-described embodiments can be used for calculating precision in measurement of mass-produced electronic components, such as frequency-impedance characteristics of chip inductors; capacitance, loss factors, and the like of chip capacitors; frequency-dependent attenuation of filters; and characteristic values of semiconductor devices and sensors. Needless to say, the product stratification device is also capable of calculating precision in measurement of outer profiles, such as dimensions, shapes, and colors, of components including not only electronic components, but also other components.

### DESCRIPTION OF REFERENCE SYMBOLS

1: Measuring part
2: Operation processing part
3: Stratifying module
4: Deemed standard deviation calculating module
5: Re-stratifying module
6: Rank-by-rank estimation number calculating module
7: Variation calculating module
10: Product
21: CPU
22: Memory
23: Storage device
24: I/O interface
25: Video interface
26: Portable disc drive
27: Measurement interface
28: Internal bus
90: Portable recording medium
230: Computer program
241: Keyboard
242: Mouse
251: Display device

1. A product stratification system comprising:
a measuring device configured to measure characteristic values for a plurality of products, with the characteristic values indicating at least one predetermined characteristic of the products;
a stratifying module configured to stratify the products into a predetermined plurality of ranks based on the measured characteristic values;
a deemed standard deviation calculator configured to calculate, for each of the plurality of products, an average of the measured characteristic values and a deemed standard deviation that corresponds to a standard deviation for variation in the characteristic values;
a re-stratifying module configured to re-measure the characteristic values for each of the plurality of products that belong to at least one of the predetermined plurality of ranks based on a stratification by the stratifying module and to re-stratify the plurality of products into the predetermined plurality of ranks based on the re-measured characteristic values;
an estimation number calculator configured to estimate, for each of the plurality of products, an estimation number of respective portions of the products that belong to each of the predetermined plurality of ranks based on a probability distribution for the average and the deemed standard deviation for the plurality of products; and
a variation calculator configured to calculate a measured value variation of each of the plurality of products based on the estimation number, the measured value variation indicative of whether at least a portion of the plurality of products are defective or non-defective.

2. The product stratification device according to claim 1, wherein the predetermined plurality of ranks are based on a predetermined inspection standard that defines upper and lower limits of the characteristic values configured for determining whether each of the plurality of products is a non-defective product.

3. The product stratification device according to claim 2, wherein the re-stratifying module is further configured to re-stratify the plurality of products that belong to one of the predetermined plurality of ranks that has a range of the characteristic values between the lower and upper limits defined by the predetermined inspection standard.

4. The product stratification device according to claim 3, wherein the variation calculator is further configured to calculate a consumer's risk and a producer's risk from the estimation number of each of the plurality of products that belong to each of the predetermined plurality of ranks and to calculate the measured value variation in which a value obtained by multiplying a sum of the calculated consumer's risk and the calculated producer's risk by a total number of the products is equal to an actual number of the products determined to be defective products.

5. The product stratification device according to claim 2, wherein the re-stratifying module is further configured to re-stratify the plurality of products that belong to one of the predetermined plurality of ranks that has a range of the characteristic values greater than the upper limit defined by the predetermined inspection standard and the products that belong to one of the predetermined plurality of ranks that has a range of the characteristic values lower than the lower limit defined by the predetermined inspection standard.

6. The product stratification device according to claim 5, wherein the variation calculator is configured to calculate a consumer's risk and a producer's risk from the estimation number for the plurality of products that belong to each of the predetermined plurality of ranks and to calculate the measured value variation in which a value obtained by multiplying a sum of the calculated consumer's risk and the calculated producer's risk by a total number of the products is equal to an actual number of the products determined to be defective products.

7. The product stratification device according to claim 1, wherein the plurality of products are capacitors and the measuring device is configured to measure a capacitance as the measured characteristic values of the plurality of capacitors.

8. A method for product stratification to classify products as either defective or non-defective, the method comprising:
measuring, by a measuring device, characteristic values for a plurality of products, with the characteristic values indicating at least one predetermined characteristic of the products;
stratifying the products into a predetermined plurality of ranks based on the measure characteristic values;
calculating, for each of the plurality of products, an average of the measure characteristic values and a deemed standard deviation that corresponds to a standard deviation for variation in the characteristic values;
re-measuring the characteristic values for each of the plurality of products that belong to at least one of the predetermined plurality of ranks based on a stratification;
re-stratifying the plurality of products into the predetermined plurality of ranks based on the re-measured characteristic values;
estimating, for each of the plurality of products, an estimation number of respective portions of the products that belong to each of the predetermined plurality of ranks based on a probability distribution for the average and the deemed standard deviation for the plurality of products; and
calculating a measured value variation of each of the plurality of products based on the estimation number, the measured value variation indicative of whether at least a portion of the plurality of products are defective or non-defective.

9. The method according to claim 8, wherein the predetermined plurality of ranks are based on a predetermined inspection standard that defines upper and lower limits of the characteristic values configured for determining whether each of the plurality of products is a non-defective product.

10. The method according to claim 9, further comprising:
re-stratifying the plurality of products that belong to one of the predetermined plurality of ranks that has a range of the characteristic values between the lower and upper limits defined by the predetermined inspection standard.

11. The method according to claim 10, further comprising:
calculating a consumer's risk and a producer's risk from the estimation number of each of the plurality of products that belong to each of the predetermined plurality of ranks; and
calculating the measured value variation in which a value obtained by multiplying a sum of the calculated consumer's risk and the calculated producer's risk by a total number of the products is equal to an actual number of the products determined to be defective products.

12. The method according to claim 10, further comprising:
re-stratifying the plurality of products that belong to one of the predetermined plurality of ranks that has a range of the characteristic values greater than the upper limit defined by the predetermined inspection standard and the products that belong to one of the predetermined plurality of ranks that has a range of the characteristic values lower than the lower limit defined by the predetermined inspection standard.

13. The method according to claim 12, further comprising:
calculating a consumer's risk and a producer's risk from the estimation number for the plurality of products that belong to each of the predetermined plurality of ranks; and
calculating the measured value variation in which a value obtained by multiplying a sum of the calculated consumer's risk and the calculated producer's risk by a total number of the products is equal to an actual number of the products determined to be defective products.

14. A computer program executable in a product stratification device configured to stratify products, the computer program causing the product stratification device to:
measure characteristic values for a plurality of products, with the characteristic values indicating at least one predetermined characteristic of products;
stratify the products into a predetermined plurality of ranks based on the measured characteristic values;
calculate, for each of the plurality of products, an average of the measured characteristic values measured and a deemed standard deviation that corresponds to a standard deviation for variation in the characteristic values;
re-measure the characteristic values for each of the plurality of products that belong to at least one of the predetermined plurality of ranks based on a stratification and re-stratify the plurality of products into the predetermined plurality of ranks based on the re-measured characteristic values;
estimate, for each of the plurality of products, an estimation number of respective portions of the products that belong to each of the predetermined plurality of ranks based on a probability distribution for the average and the deemed standard deviation for the plurality of products; and
calculate a measured value variation of each of the plurality of products based on the estimation number, the measured value variation indicative of whether at least a portion of the plurality of products are defective or non-defective.

15. The computer program according to claim 14, wherein the predetermined plurality of ranks are based on a predetermined inspection standard that defines upper and lower limits of the characteristic values configured for determining whether each of the plurality of products is a non-defective product.

16. The computer program according to claim 15, wherein the computer program further causes the product stratification device to re-stratify the plurality of products that belong to one of the predetermined plurality of ranks that has a range of the characteristic values between the lower and upper limits defined by the predetermined inspection standard.

17. The computer program according to claim 16, wherein the computer program further causes the product stratification device to:
calculate a consumer's risk and a producer's risk from the estimation number of each of the plurality of products that belong to each of the predetermined plurality of ranks, and
calculate the measured value variation in which a value obtained by multiplying a sum of the calculated consumer's risk and the calculated producer's risk by a total number of the products is equal to an actual number of the products determined to be defective products.

18. The computer program according to claim 15, wherein the computer program further causes the product stratification device to re-stratify the plurality of products that belong to one of the predetermined plurality of ranks that has a range of the characteristic values greater than the upper limit defined by the predetermined inspection standard and the products that belong to one of the predetermined plurality of ranks that has a range of the characteristic values lower than the lower limit defined by the predetermined inspection standard.

19. The computer program according to claim 18, wherein the computer program further causes the product stratification device to:
calculate a consumer's risk and a producer's risk from the estimation number for the plurality of products that belong to each of the predetermined plurality of ranks, and
calculate the measured value variation in which a value obtained by multiplying a sum of the calculated consumer's risk and the calculated producer's risk by a total number of the products is equal to an actual number of the products determined to be defective products.

20. The computer program according to claim 14, wherein the plurality of products are capacitors and the computer program causes the product stratification device to measure a capacitance as the measured characteristic values of the plurality of capacitors.
